(19) United States
(12) Patent Application Publication
(10) Pub. No.: US 2026/0129820 A1
(43) Pub. Date: May 7, 2026

(54) CONNECTIONS TO SOURCE/DRAIN FEATURES

(71) Applicant: Taiwan Semiconductor Manufacturing Company, Ltd., Hsin-Chu (TW)

(72) Inventors: Shih-Hao Lin, Hsinchu (TW); Chih-Hsiang Huang, Zhubei City (TW); Yu-Bey Wu, Hsinchu City (TW); Ping-Wei Wang, Hsin-Chu (TW)

(21) Appl. No.: 19/073,588

(22) Filed: Mar. 7, 2025

Related U.S. Application Data
(60) Provisional application No. 63/717,567, filed on Nov. 7, 2024.

(51) Int. Cl. H10B 10/00; H10D 30/00; H10D 30/43; H10D 62/10; H10D 62/13; H10D 64/23

(52) U.S. Cl. CPC H10B 10/12; H10B 10/18; H10D 30/43; H10D 30/502; H10D 62/102; H10D 62/121; H10D 62/151; H10D 64/256

(57) ABSTRACT

Semiconductor structures and methods of fabricating the semiconductor structures are described. An exemplary method includes receiving an intermediate structure comprising an n-type transistor and a p-type transistor, forming a dielectric structure under the n-type transistor and the p-type transistor, forming a first trench and a second trench each extending through the dielectric structure, the first trench exposing a bottom surface of a source/drain feature of the n-type transistor, the second trench exposing a bottom surface of a source/drain feature of the p-type transistor, wherein a depth of the second trench is greater than a depth of the first trench, forming a first silicide layer and a second silicide layer in the first trench and the second trench, respectively, and forming a first backside via and a second backside via in the first trench and the second trench, respectively.

### PRIORITY DATA

This application claims priority to U.S. Provisional Patent Application Ser. No. 63/717,567, filed Nov. 7, 2024, the entire disclosure of which is hereby incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs. Integrated circuits include a variety of circuit device components, such as transistors. Transistors with different configurations may be suitable for different circuit functions due to their different performance characteristics. While existing transistors and methods for forming transistors are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a diagrammatic plan view of an IC structure, in portion or entirety, according to various aspects of the present disclosure.

FIGS. 1B and 1C are diagrammatic plan views of an array of memory cells, such as static random-access memory (SRAM) cells, in portion or entirety, according to various aspects of the present disclosure.

FIG. 2 is a circuit diagram of a memory cell, such as an SRAM cell, that can be implemented in the IC structure of FIG. 1, according to various aspects of the present disclosure.

FIG. 3 illustrates a flowchart of an exemplary method for fabricating source/drain contacts for a memory cell, such as an SRAM cell, according to various embodiments of the present disclosure.

FIG. 4 is an exemplary layout of a memory cell, such as an SRAM cell, in portion or entirety, according to various aspects of the present disclosure.

FIGS. 5A, 6A, 7A, 8A, 9A, 10A, and 11A illustrate fragmentary cross-sectional views of an intermediate structure including the SRAM cell taken along line A-A as shown in FIG. 4 during various fabrication stages in the method of FIG. 3, according to various aspects of the present disclosure.

FIGS. 5B, 6B, 7B, 8B, 9B, 10B, and 11B illustrate fragmentary cross-sectional views of the intermediate structure taken along line B-B as shown in FIG. 4 during various fabrication stages in the method of FIG. 3, according to various aspects of the present disclosure.

FIG. 12 is an exemplary layout of a portion of the IC structure including the SRAM cell and source/drain contacts, according to various aspects of the present disclosure.

FIG. 13 illustrates a flowchart of an exemplary method for fabricating backside vias for a memory cell, such as the SRAM cell, according to various embodiments of the present disclosure.

FIGS. 14A, 15A, 16A, 17A, 18A, 19A, 20A, 21A, 22A, 23A, and 24A illustrate fragmentary cross-sectional views of an intermediate structure including the SRAM cell taken along line A-A as shown in FIG. 4 during various fabrication stages in the method of FIG. 13, according to various aspects of the present disclosure.

FIGS. 14B, 15B, 16B, 17B, 18B, 19B, 20B, 21B, 22B, 23B, and 24B illustrate fragmentary cross-sectional views of the intermediate structure taken along line B-B as shown in FIG. 4 during various fabrication stages in the method of FIG. 13, according to various aspects of the present disclosure.

FIG. 25 is an exemplary layout of a portion of the IC structure including the SRAM cell and backside vias, according to various aspects of the present disclosure.

FIGS. 26A and 26B illustrate fragmentary cross-sectional views of an alternative IC structure taken along line A-A, B-B as shown in FIG. 4, according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Multi-gate devices, such as fin field-effect transistors (FinFETs) and gate-all-around (GAA) transistors, have been introduced in an effort to improve gate control by increasing gate-channel coupling, reduce OFF-state current, and reduce short-channel effects (SCEs). A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. The channel region of a GAA transistor may be formed from nanowires, nanosheets, or other nanostructures and for that reasons, a GAA transistor may also be referred to as a nanowire transistor or a nanosheet transistor. The three-dimensional structure of the multi-gate devices allows them to be aggressively scaled while maintaining gate control and mitigating SCEs.

An n-type transistor (e.g., NFET) includes a pair of n-type doped source/drain features, and its majority carrier is electrons. A p-type transistor (PFET) includes a pair of p-type doped source/drain features, and its majority carrier is holes. Due to various reasons, when PFET and NFETs are fabricated to have similar configurations (e.g., same channel length), PFETs may have better performance than NFETs. Multi-gate NFETs and multi-gate PFETs may be implemented in a static random-access memory (SRAM) device. An SRAM device is a type of semiconductor memory that uses bi-stable latching circuity (e.g., flip-flop) to store binary bits of information. A typical SRAM cell may include pull-up (PU) transistors, pull-down (PD) transistors, and pass-gate (PG) transistors. As semiconductor technology nodes continue to advance to smaller generations (e.g., smaller than the 10-nanometer node), the SRAM write and read margins may become more important. An alpha ratio of the SRAM—defined as PU's Idₛₐₜ (saturation current) divided by PG's Idₛₐₜ—may be tuned to achieve the desired write and/or read margin of the SRAM. However, for SRAM cells, with greater device drive currents for pull-up transistors, although read operations are improved, write margins of the SRAM cells are degraded. For high performance SRAM cells, read and write operations are preferably balanced. Therefore, it is desirable to improve the write margins of the SRAM cells without substantially affecting the cell speed.

The present disclosure provides a semiconductor structure including an SRAM cell with an improved write margin without substantially affecting the cell speed and a method for forming the same. In an embodiment, a first backside via is disposed under and electrically coupled to a source of a pull-up transistor of the SRAM cell, and a second backside via is disposed under and electrically coupled to a source of a pull-down transistor of the SRAM cell. To achieve NFETs and PFETs with balanced performance, during the formation of the first backside via and the second backside via, the source of the pull-up transistor is partially removed, thereby reducing a volume of the source of the pull-up transistor and thus decreasing the saturation current Idₛₐₜ of the pull-up transistor. By reducing the saturation current Idₛₐₜ of pull-up transistors in SRAM cells, write margins of SRAM cells may be advantageously improved. Meanwhile, the source of the pull-down transistor are not intentionally recessed during the forming of the second backside via. Thus, the pull-down transistor may have less current crowding issue than the pull-up transistor.

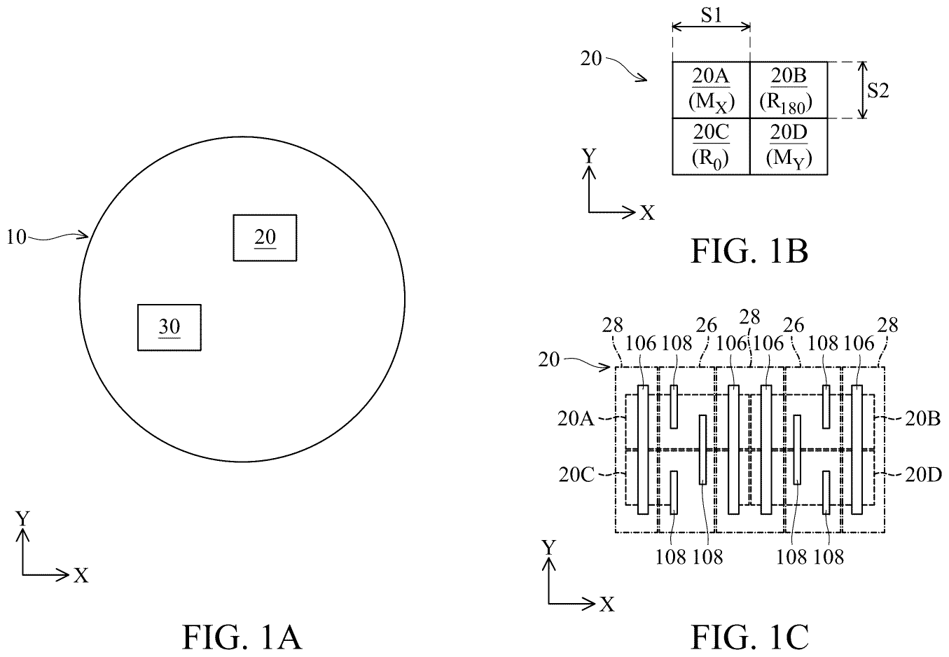

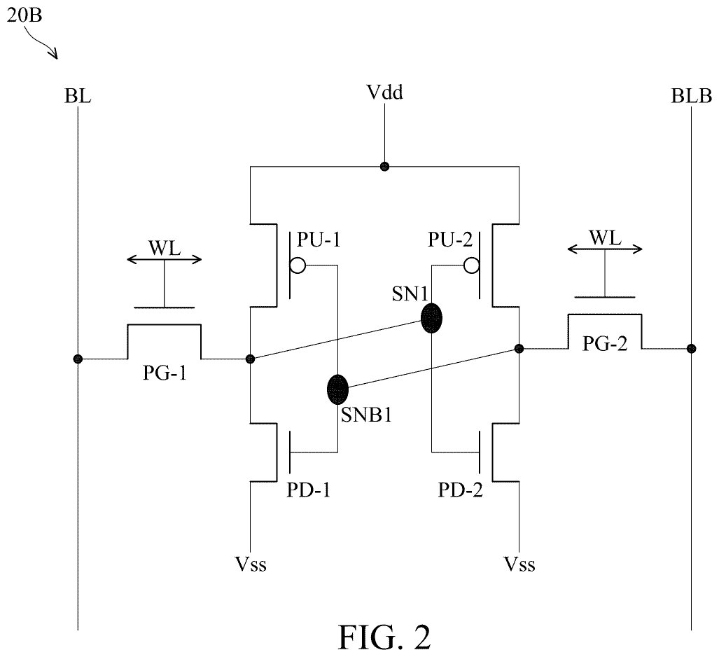

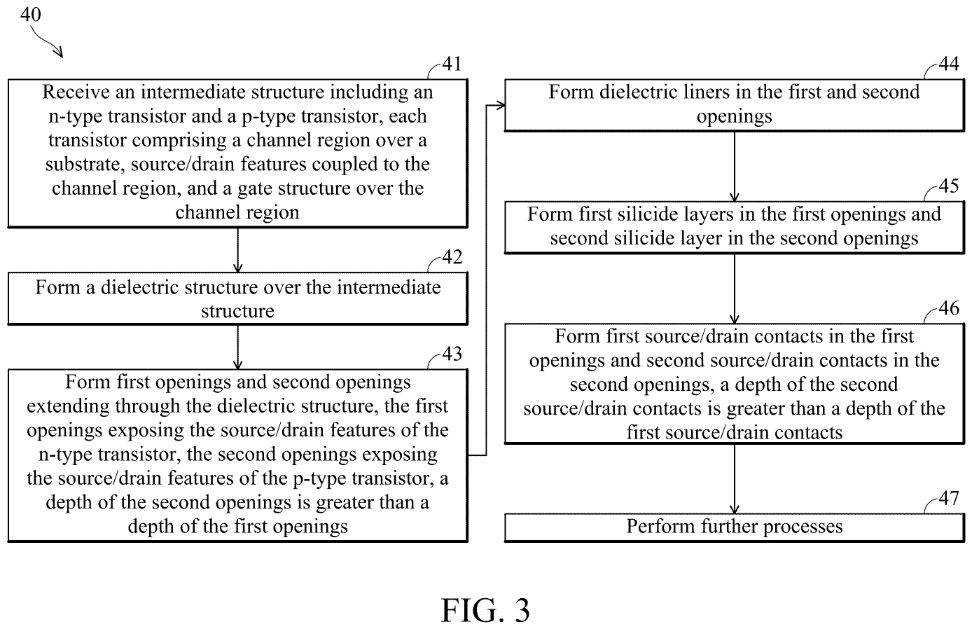

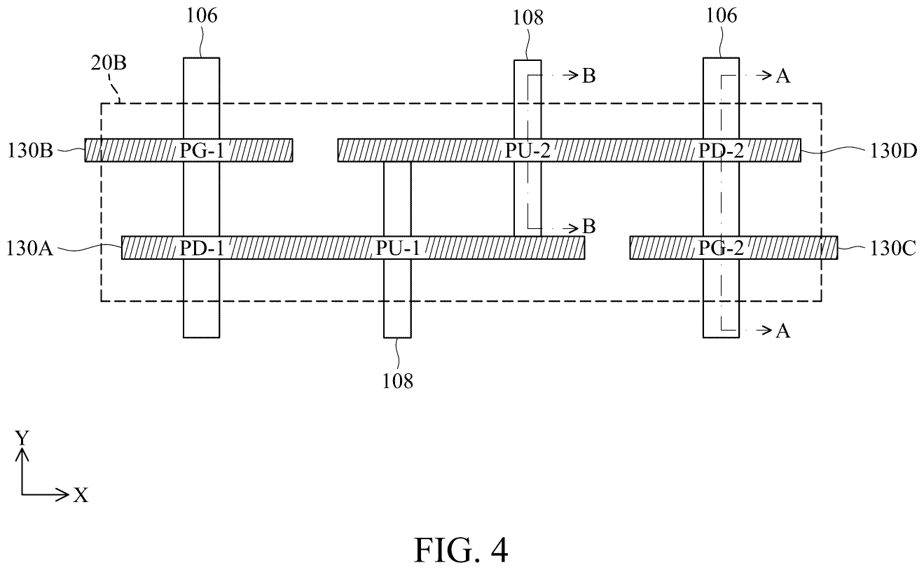

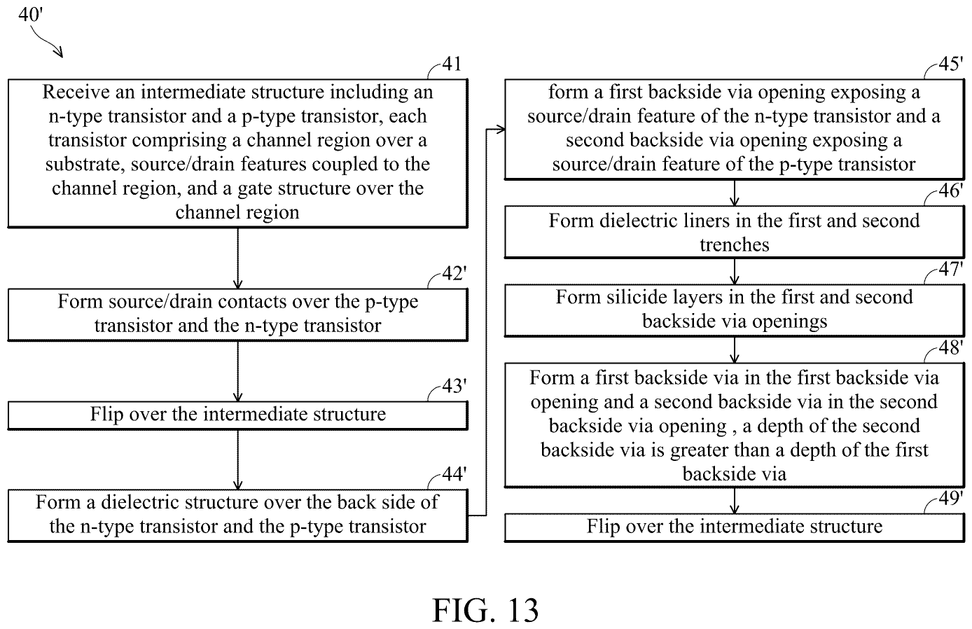

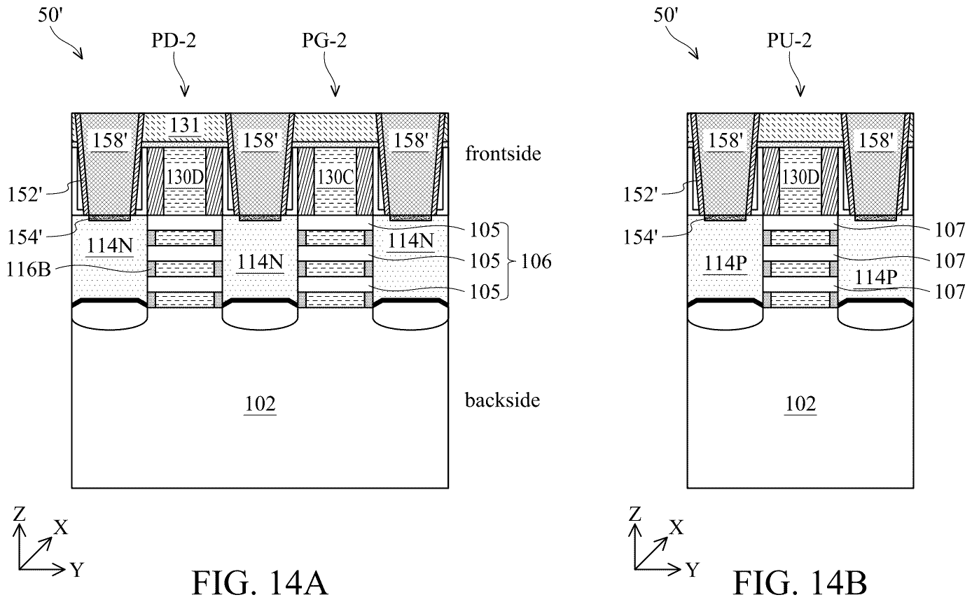

The various aspects of the present disclosure will now be described in more detail with reference to the figures. In that regard, FIG. 1A is a diagrammatic plan view of an exemplary IC structure 10. FIGS. 1B and 1C are diagrammatic plan views of an array of memory cells, such as static random-access memory (SRAM) cells 20A-20D, in portion or entirety, according to various aspects of the present disclosure. FIG. 2 is a circuit diagram of an SRAM cell 20B that can be implemented in the IC structure of FIG. 1. FIG. 3 is a flow chart illustrating method 40 of forming source/drain contacts for the SRAM cells 20B. Method 40 is described below in conjunction with FIGS. 4-12. FIG. 13 is a flow chart illustrating another alternative method 40′ for forming backside vias for the SRAM cell 20B. Method 40′ is described below in conjunction with FIGS. 14A-26B. Method 40 and method 40′ are merely examples and are not intended to limit the present disclosure to what is explicitly illustrated therein. Additional steps may be provided before, during, and/or after the method, and some steps described can be replaced, eliminated, or moved around for additional embodiments of the method. Not all steps are described herein in detail for reasons of simplicity. For avoidance of doubts, the X, Y and Z directions in FIGS. 4-12 and 14A-26B are perpendicular to one another and are used consistently throughout the present disclosure. Throughout the present disclosure, like reference numerals denote like features unless otherwise excepted. In the present disclosure, frontside features (e.g., frontside source/drain contacts, frontside source/drain vias) may be referred to as features that are formed over a top surface of an intermediate structure, and backside features (e.g., backside vias) may be referred to as features that are formed under a bottom surface of the intermediate structure.

Referring to FIG. 1A, the present disclosure provides an IC structure 10 formed over a semiconductor substrate and includes at least an array 20 of memory cells. The array 20 may include static random-access memory (SRAM) cells, dynamic random-access memory (DRAM) cells, non-volatile random-access memory (NVRAM) cells, flash memory cells, other suitable memory cells, or combinations thereof. The IC structure 10 may further include a number of other components, such as an array 30 of standard logic (STD) cells configured to provide various standard logic devices, such as inverter, AND, NAND, OR, XOR, NOR, other suitable devices, or combinations thereof. Additionally, the IC structure 10 may include various passive and active microelectronic devices, such as resistors, capacitors, inductors, diodes, bipolar transistors, high voltage transistors, high frequency transistors, other suitable devices, or combinations thereof. Additional features can be added to the IC structure 10 and some of the features described below can be replaced, modified, or eliminated in other embodiments of the IC structure 10.

In the present embodiments, referring to FIG. 1B, the array 20 includes a number of SRAM cells 20A, 20B, 20C, and 20D, which generally provide memory or storage capable of retaining data when power is applied. As such, the array 20 is hereafter referred to as SRAM array 20. The SRAM cells 20A, 20B, 20C, and 20D, together defining a two-by-two grid, exhibit mirror and/or rotational symmetry with respect to each other. For example, using the SRAM cell 20C as a reference (denoted “R₀”), a layout of the SRAM cell 20A (denoted “M_{X}”) is a mirror image of a layout of the SRAM cell 20C with respect to the X-axis. Similarly, a layout of the SRAM cell 20B is a mirror image of the layout of the SRAM cell 20A, and a layout of the SRAM cell 20D (denoted “M_{Y}”) is a mirror image of the layout of the SRAM cell 20C, both with respect to the Y-axis. In other words, the layout of the SRAM cell 20B (denoted “R₁₈₀”) is symmetric to the layout of the SRAM 20C by a rotation of 180 degrees about a geometric center of the grid, which is defined as an intersection point of an imaginary line bisecting the rectangular grid along the Y-axis and an imaginary line bisecting the rectangular grid along the X-axis. Furthermore, in the depicted embodiments, the SRAM cells 20A-20D are substantially the same in size, i.e., having substantially the same horizontal (long) pitch S1 along the X-axis and a vertical (short) pitch S2 along the Y-axis. In the present embodiments, each of the SRAM cells 20A-20D includes one or more GAA transistors to be discussed in detail below.

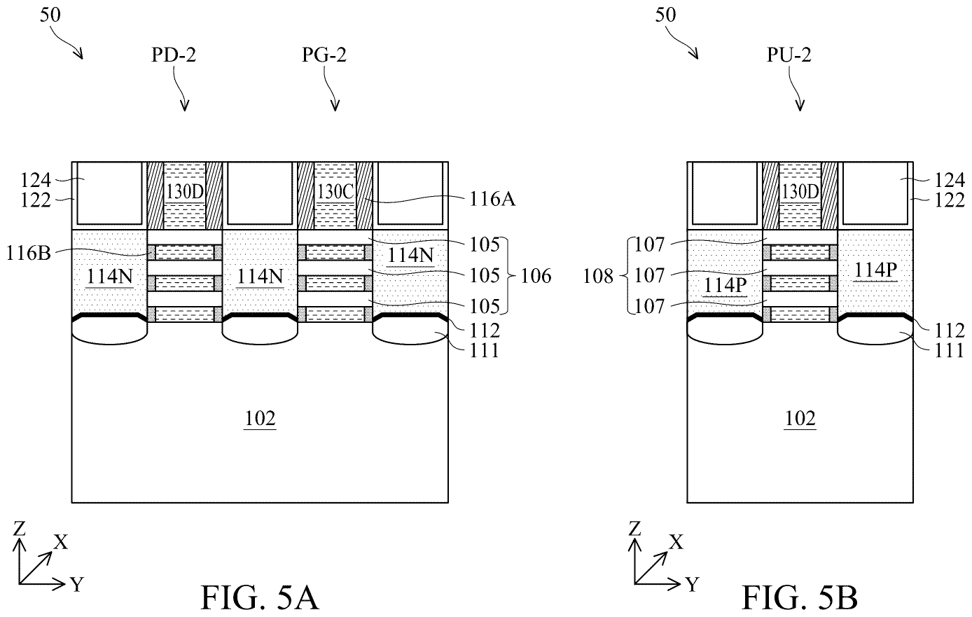

Referring to FIG. 1C, each of the SRAM cells 20A-20D is configured to include active regions 106 each disposed over a p-type doped region 28 (hereafter referred to as p-well 28) and active regions 108 each disposed over a n-type doped region 26 (hereafter referred to as n-well 26), which is interposed between two p-wells 28. The active regions 106 and the active regions 108 are oriented lengthwise along Y-axis and spaced from each other along X-axis, which is substantially perpendicular to the Y-axis. As will be discussed in detail below, each active region 106 includes a set of vertically stacked semiconductor layers (e.g., channel layers 105 shown in FIG. 5A) configured to provide channel regions of n-type GAA transistors, and each active region 108 includes a set of vertically stacked semiconductor layers (e.g., channel layers 107 shown in FIG. 5B) configured to provide channel regions of p-type GAA transistors. Various aspects and embodiments of the SRAM cells 20A-20D are discussed in detail below.

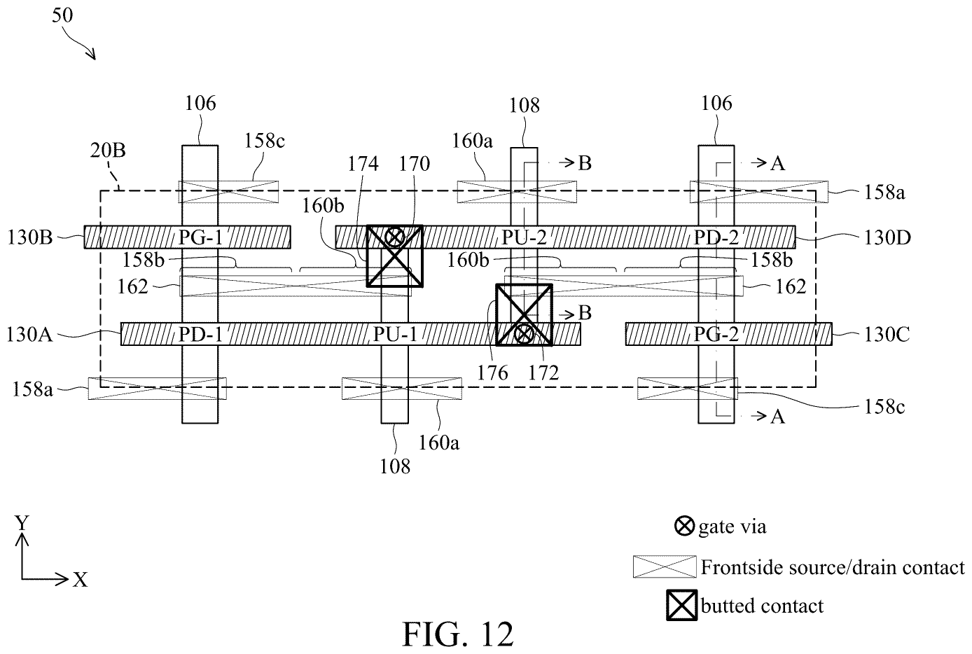

FIG. 2 illustrates an exemplary circuit schematic for the SRAM cell 20B. In this illustrated embodiment, each SRAM cell is a single-port SRAM cell (e.g., 1-bit SRAM cell). In some other embodiments, the SRAM cell may be a dual-port SRAM cell and may include any suitable number of transistors. The single-port SRAM cell 20B in this illustrated embodiment includes pull-up transistors PU-1, PU-2; pull-down transistors PD-1, PD-2; and pass-gate transistors PG-1, PG-2. As show in the circuit diagram, transistors PU-1 and PU-2 are p-type transistors, and transistors PG-1, PG-2, PD-1, and PD-2 are n-type transistors. The drains of pull-up transistor PU-1 and pull-down transistor PD-1 are coupled together, and the drains of pull-up transistor PU-2 and pull-down transistor PD-2 are coupled together. Transistors PU-1 and PD-1 are cross-coupled with transistors PU-2 and PD-2 to form a first data latch. The gates of transistors PU-2 and PD-2 are coupled together and to the drains of transistors PU-1 and PD-1 to form a first storage node SN1, and the gates of transistors PU-1 and PD-1 are coupled together and to the drains of transistors PU-2 and PD-2 to form a complementary first storage node SNB1. Sources of the pull-up transistors PU-1 and PU-2 are coupled to power voltage Vdd, and the sources of the pull-down transistors PD-1 and PD-2 are coupled to a voltage Vss, which may be an electrical ground in some embodiments. In some embodiments, gates of transistors PU-2 and PD-2 are coupled to the drains of transistors PU-1 and PD-1 by a first butted contact(e.g., butted contact 174 shown in FIG. 12), and the gates of transistors PU-1 and PD-1 are coupled to the drains of transistors PU-2 and PD-2 by a second butted contact (e.g., butted contact 176 shown in FIG. 12). The first storage node SN1 of the first data latch is coupled to bit line BL through pass-gate transistor PG-1, and the complementary first storage node SNB1 is coupled to complementary bit line BLB through pass-gate transistor PG-2. The first storage node SN1 and the complementary first storage node SNB1 are complementary nodes that are often at opposite logic levels (logic high or logic low). Gates of pass-gate transistors PG-1 and PG-2 are coupled to a word line WL. An alpha ratio of the SRAM—defined as PU's Idₛₐₜ (saturation current) divided by PG's Idₛₐₜ—may be tuned to achieve the desired write and/or read margin of the SRAM. A read margin of the SRAM improves as the alpha ratio increases, but a write margin of the SRAM improves as the alpha ratio decreases. In this present disclosure, performance of the pull-up transistors are adjusted to improve the write margin of the SRAM without significantly affecting the cell speed.

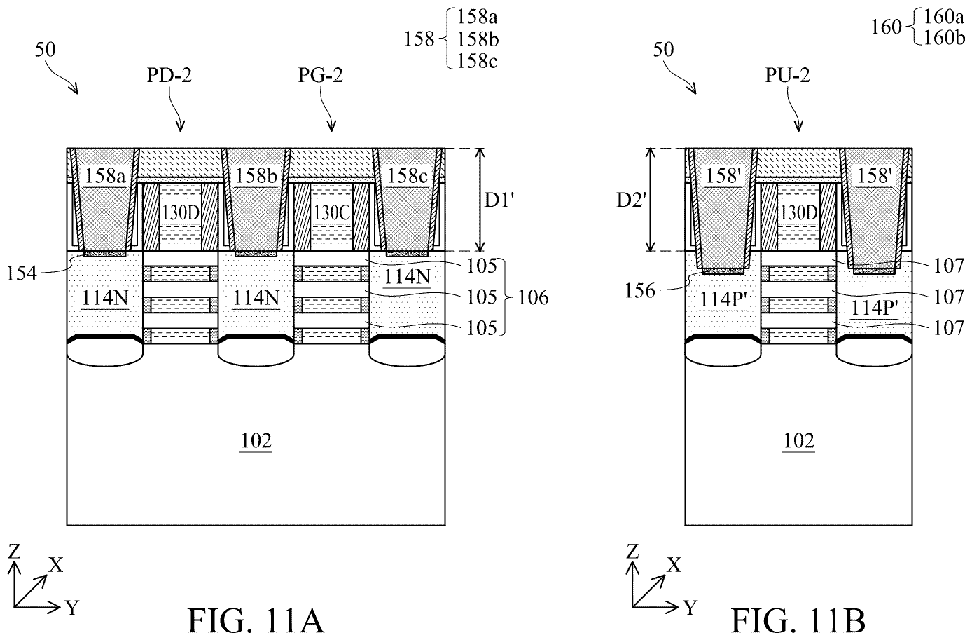

FIG. 3 illustrates a flowchart of an exemplary method 40 for fabricating source/drain contacts 158 and 160 (shown in FIGS. 11A-11B) for the SRAM cell 20B, according to various embodiments of the present disclosure. Method 40 is described below with reference to FIGS. 4-15.

Referring now to FIGS. 3, 4, and 5A-5B, method 40 includes a block 41 where an intermediate structure 50 is received. The intermediate structure 50 includes the SRAM cell 20B. FIG. 4 depicts an exemplary layout of the SRAM cell 20B, according to various aspects of the present disclosure. It is understood that the SRAM cell 20B may have other layouts. FIGS. 5A and 5B illustrate fragmentary cross-sectional views of the intermediate structure 50 taken along line A-A and line B-B shown in FIG. 4, respectively, according to various aspects of the present disclosure.

With reference to FIGS. 4 and 5A-5B, the SRAM cell 20B (as a portion of the IC structure 10) is formed over a substrate (or a wafer) 102 having a number of p-wells (not shown in FIGS. 5A-5B) and n-wells (not shown in FIGS. 5A-5B) formed therein (and/or thereover) according to various design requirements of the SRAM array 20. In the present embodiments, the substrate 102 includes silicon. Alternatively, or additionally, the substrate 102 includes another elementary semiconductor, such as germanium; a compound semiconductor, such as silicon carbide, silicon phosphide, gallium arsenide, gallium phosphide, indium phosphide, indium arsenide, and/or indium antimonide; an alloy semiconductor, such as SiGe, SiPC, GaAsP, AlInAs, AlGaAs, GaInAs, GaInP, and/or GaInAsP; or combinations thereof. In some embodiments, the substrate 102 is a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, other suitable methods, or combinations thereof. The n-well (e.g., n-well 26) is configured to provide at least one p-type field-effect transistor (PFET), such as a pull-up transistor, and the p-well (e.g., p-well 28) is configured to provide at least one n-type field-effect transistor (NFET), such as a pull-down transistor or a pass-gate transistor. Each n-well may be doped with an n-type dopant, such as phosphorus, arsenic, other n-type dopants, or combinations thereof. Each p-well may be doped with a p-type dopant, such as boron, indium, other p-type dopants, or combinations thereof. In some embodiments, the substrate 102 may include additional doped regions configured to provide one or more transistors according to design requirements of the SRAM array 20. In some embodiments, the substrate 102 includes doped regions formed with a combination of p-type dopants and n-type dopants. The various doped regions can be formed directly on and/or in the substrate 102, for example, providing a p-well structure, an n-well structure, a dual-well structure, a raised structure, or combinations thereof. Each of the various doped regions may be formed by performing an ion implantation process, a diffusion process, other suitable doping processes, or combinations thereof.

In embodiments represented in FIG. 4, the SRAM cell 20B includes two active regions 106 each disposed in a p-type well and two active regions 108 disposed in an n-type well interposing between the two p-type wells. In an illustrated embodiment, with reference to FIGS. 5A-5B, each active region 106 includes a stack of semiconductor layers 105; similarly, and each active region 108 includes a stack of semiconductor layers 107. In the depicted embodiments, the semiconductor layers 105 and 107 are generally oriented lengthwise along the Y-axis and stacked vertically along the Z-axis. Each of the channel layers 105 and 107 may include Si, Ge, SiC, SiGe, GeSn, SiGeSn, SiGeCSn, other suitable semiconductor materials, or combinations thereof. In the present embodiments, each of the semiconductor layers 105 and 107 includes Si in the form of a nanosheet, a nanowire (e.g., a nanowire having a hexagonal cross-section), a nanorod (e.g., a nanorod having a square or round cross-section), or other suitable configurations. In some embodiments, the active region 106 and the active region 108 each include two to ten channel layers 105 and 107, respectively. For example, the active region 106 and the active region 108 may each include three channel layers 105 and three channel layers 107, respectively. Of course, the present disclosure is not limited to such configurations and the number of semiconductor layers may be tuned according to design requirements for the IC structure 10. Although not shown, the SRAM cell 20B further includes isolation structures (not shown) disposed over the substrate 102 to electrically separate various active regions formed over the substrate 102. The isolation structures may include shallow trench isolation (STI) features.

Furthermore, each stack of the semiconductor layers 105 interposes n-type source/drain (S/D) features 114N (shown in FIG. 5A), and each stack of the semiconductor layers 107 interposes p-type S/D features 114P (shown in FIG. 5B). Source/drain feature(s) may refer to a source or a drain, individually or collectively dependent upon the context. Exemplary n-type source/drain features 114N may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. Exemplary p-type source/drain features 114P may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process. In some embodiments, the n-type source/drain features 114N and/or the p-type source/drain features 114P each may be a multi-layer structure that includes an undoped semiconductor layer, a lightly doped semiconductor layer, and a heavily doped semiconductor layer.

In various embodiments, the SRAM cell 20B may also include undoped semiconductor layers 111 (shown in FIGS. 5A-5B) disposed between the source/drain features (e.g., source/drain features 114N and/or source/drain features 114P) and the substrate 102. The undoped semiconductor layer 111 may be formed using an epitaxial process and is undoped or not intentionally doped. In some embodiments, the undoped semiconductor layer 111 may include undoped silicon (Si), undoped germanium (Ge), undoped silicon germanium (SiGe), or other suitable materials. In this depicted example, a top surface of the undoped semiconductor layer 111 has a convex profile.

The SRAM cell 20B may also include insulation layers 112 (shown in FIGS. 5A-5B) formed on the undoped semiconductor layers 111. In an exemplary process, a dielectric material layer (not shown) may be deposited over the substrate 102 by using a chemical vaper deposition (CVD), physical vaper deposition (PVD), atomic layer deposition (ALD) or other suitable processes, and the deposition thickness of the dielectric material layer may be dependent on desired thicknesses of the insulation layer 112 that will be formed on the undoped semiconductor layer 111. In an embodiment, the dielectric material layer is deposited by using a physical vaper deposition (PVD) process. Then, the dielectric material layer is etched back, leaving portions of the dielectric material layer formed on a top or planar surface, thereby forming the insulation layers 112. In some embodiments, the insulation layer may include silicon oxide, silicon nitride, silicon carbide, or other suitable materials. In some embodiments, the insulation layers 112 may be only formed for n-type transistors (e.g., pull-down transistors and pass gate transistors) and is not formed for P-type transistors (e.g., pull-up transistors). In some other embodiments, the insulation layers 112 may be omitted.

Still referring to FIGS. 4 and 5A-5B, each SRAM cell 20B further includes gate structures, such as gate structures 130A, 130B, 130C, and 130D, oriented lengthwise along the X-axis. As illustrated by FIG. 4, each gate structure 130A-130D traverses a channel region of the active region 106 and/or a channel region of the active region 108. In the present embodiments, the semiconductor layers 105 are suspended in (or wrapped around by) one or more of the gate structures 130A-130D (e.g., the gate structure 130D and gate structure 130C as depicted in FIG. 5A) to form n-type GAA transistors, and the semiconductor layers 107 are suspended in (or wrapped around by) one of the gate structures 130A-130D (e.g., the gate structure 130D depicted in FIG. 5B) to form p-type GAA transistors. In other words, each stack of the semiconductor layers 105 is wrapped around by a portion of the gate structure 130A-130D to form a channel region of an n-type GAA transistor, and each stack of the semiconductor layers 107 is wrapped around by a portion of the gate structure 130A-130D to form a channel region of a p-type GAA transistor. As such, the semiconductor layers 105 are hereafter referred to as channel layers 105, and the semiconductor layers 107 are hereafter referred to as channel layers 107 for purposes of clarity. In the depicted embodiments, referring to FIG. 4 as an example, portions of the gate structure 130A extends over one of the active regions 106 and one of the active regions 108 to form a pull-down transistor PD-1 and a pull-up transistor PU-1, respectively; a portion of the gate structure 130B engages with the one of the active region 106 to form a pass-gate transistor PG-1; a portion of the gate structure 130C engages with another one of the active regions 106 to form a pass-gate transistor PG-2; and portions of the gate structure 130D engage with the another one of the active regions 106 and the another one of the active regions 108 to form a pull-down transistor PD-2 and a pull-up transistor PU-2, respectively. In an embodiment, the PU-1 and the PU-2 are configured as p-type transistors, while the PD-1, the PD-2, the PG-1, and the PG-2 are configured as n-type transistors.

Each of the gate structures 130A-130D includes a gate dielectric layer and the metal gate electrode over the gate dielectric layer. In the present embodiments, portions of the gate dielectric layer wrap around each channel layer, such that each gate structure 130A-130D engages with the plurality of channel layers in each GAA transistor. The gate dielectric layer may include silicon oxynitride, aluminum silicon oxide, a high-k dielectric material such as hafnium oxide, zirconium oxide, lanthanum oxide, titanium oxide, yttrium oxide, strontium titanate, other suitable dielectric materials, or combinations thereof. In an embodiment, a dielectric constant of the gate dielectric layer is greater than a dielectric constant of the top spacers 116A. The gate dielectric layer may include a first dielectric material and the top spacers 116A may include a second dielectric material, and an ability to store electrical energy of the first dielectric material is greater than an ability to store electrical energy of the second dielectric material. In various embodiments, a thickness of the top spacers 116A is greater than a thickness of the gate dielectric layer. In some embodiments, the gate dielectric layer includes an interfacial layer disposed on the channel layers (e.g., channel layers 105 and/or 107) and a high-k dielectric layer over the interfacial layer. Though not depicted, each metal gate electrode may further include a bulk conductive layer disposed over at least one work function metal layer. The bulk conductive layer may include Cu, W, Ru, Co, Al, Ti, Ta, other suitable metals, or combinations thereof. In some examples, each gate structure may include one or more work function metal layer of the same conductivity type or of different conductivity types. Examples of the work function metal layers may include TiN, TaN, Ru, Mo, Al, WN, ZrSi₂, MoSi₂, TaSi₂, NiSi₂, Ti, Ag, TaAl, TaAlC, TiAlN, TaC, TaCN, TaSiN, Mn, Zr, other suitable work function materials, or combinations thereof. Various work function metal layers may be first deposited and then patterned to satisfy different requirements of threshold voltage in different GAA FETs. Additional material layers may also be included in each gate structure, such as an interfacial layer, a barrier layer, a capping layer, other suitable materials layers, or combinations thereof. Various layers of the gate structures may be deposited by any suitable method, such as chemical oxidation, thermal oxidation, atomic layer deposition (ALD), chemical vapor deposition (CVD), physical vapor deposition (PVD), plating, other suitable methods, or combinations thereof.

The formation of the transistors (e.g., PD-2, PG-2, PU-2 represented in FIGS. 5A-5B) of the SRAM cell 20B may include forming vertical stacks of alternating channel layers 105/107 (e.g., Si) and sacrificial layers (e.g., SiGe, not shown) over the substrate 102; patterning the vertical stacks and a top portion of the substrate 102 to form active regions 106 and 108; forming the isolation structures (e.g., shallow trench isolation (STI), field oxide, local oxidation of silicon (LOCOS) to insulate various components formed over the substrate 102; forming dummy gate stacks (not shown) over channel regions of the active regions 106 and 108; forming the n-type source/drain features 114N and the p-type source/drain features 114P in and over source/drain regions of the active regions 106 and 108; selectively removing the dummy gate stacks, selectively removing the sacrificial layers to release the channel layers 105/107; and forming the gate structures (e.g., gate structures 130A-130D) to wrap around and over the channel layers 105/107.

Still referring to FIGS. 5A-5B, the intermediate structure 50 also includes top spacers 116A and inner spacers 116B disposed on sidewalls of each gate structure, where the top spacers 116A are disposed over the channel layers 105 and 107 and the inner spacers 116B are disposed in the space between two vertically stacked channel layers 105 or two vertically stacked channel layers 107.

Still referring to FIGS. 5A-5B, the intermediate structure 50 also includes a contact etch stop layer (CESL) 122 and an interlayer dielectric (ILD) layer 124 deposited over the n-type source/drain features 114N and the p-type source/drain features 114P. The CESL 122 may include silicon nitride, silicon oxynitride, and/or other materials known in the art and may be formed by ALD, plasma-enhanced chemical vapor deposition (PECVD) process and/or other suitable deposition or oxidation processes. As shown in FIGS. 5A-5B, the CESL 122 may be deposited on top surfaces of the n-type source/drain features 114N and the p-type source/drain features 114P. A portion of the CESL 122 extends along a sidewall of the top spacers 116A such that the top spacers 116A is between the gate structure (e.g., the gate structures 130A-130D) and the CESL 122. The ILD layer 124 may be deposited by a PECVD process or other suitable deposition technique after the deposition of the CESL 122. The ILD layer 124 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

As described above with reference to FIG. 2, sources of the pull-up transistors PU-1 and PU-2 are coupled to the power voltage Vdd, and the sources of the pull-down transistors PD-1 and PD-2 are coupled to the voltage Vss. In this depicted method 40, frontside source/drain contacts 158 and 160 will be formed to electrically couple corresponding source/drain features of the transistors of the SRAM cell 20B to corresponding voltages (e.g., Vdd or Vss).

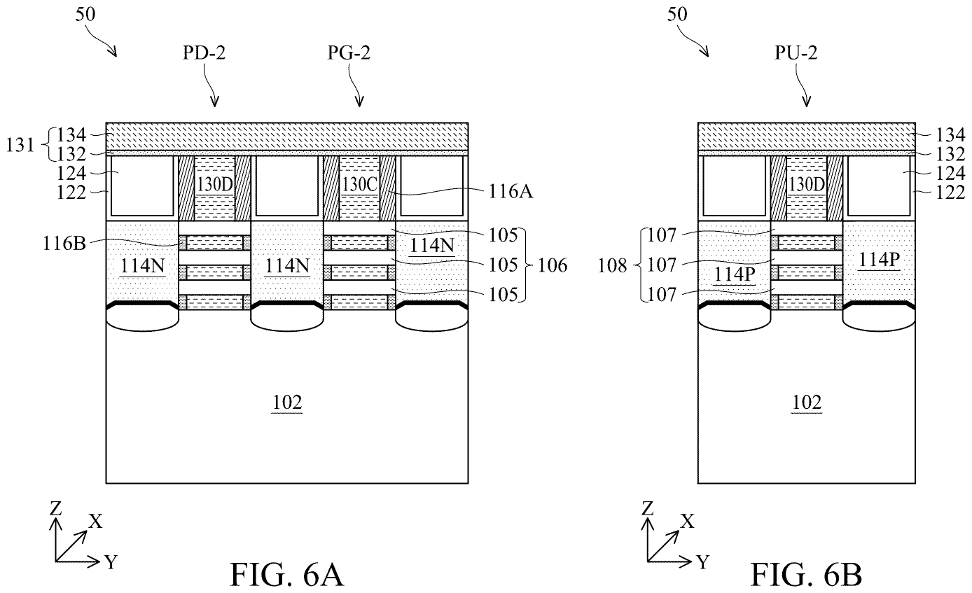

Referring now to FIG. 3 and 6A-6B, method 40 includes a block 42 where a dielectric structure 131 is formed over the intermediate structure 50. The dielectric structure 131 may include an etch stop layer 132 and an interlayer dielectric (ILD) layer 134 deposited over the etch stop layer 132. The etch stop layer 132 may include silicon nitride, silicon oxynitride, and/or other suitable materials and may be formed by ALD, plasma-enhanced chemical vapor deposition (PECVD) process and/or other suitable deposition or oxidation processes. The etch stop layer 132 may indicate an etch stop point for forming gate via openings over the gate structures 130A-130D. The ILD layer 134 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials and may be deposited by, for example, a PECVD process or other suitable deposition technique after the deposition of the etch stop layer 132. After the deposition of the ILD layer 134, a planarization process, such a chemical mechanical polishing (CMP) process may be performed to provide a planar top surface.

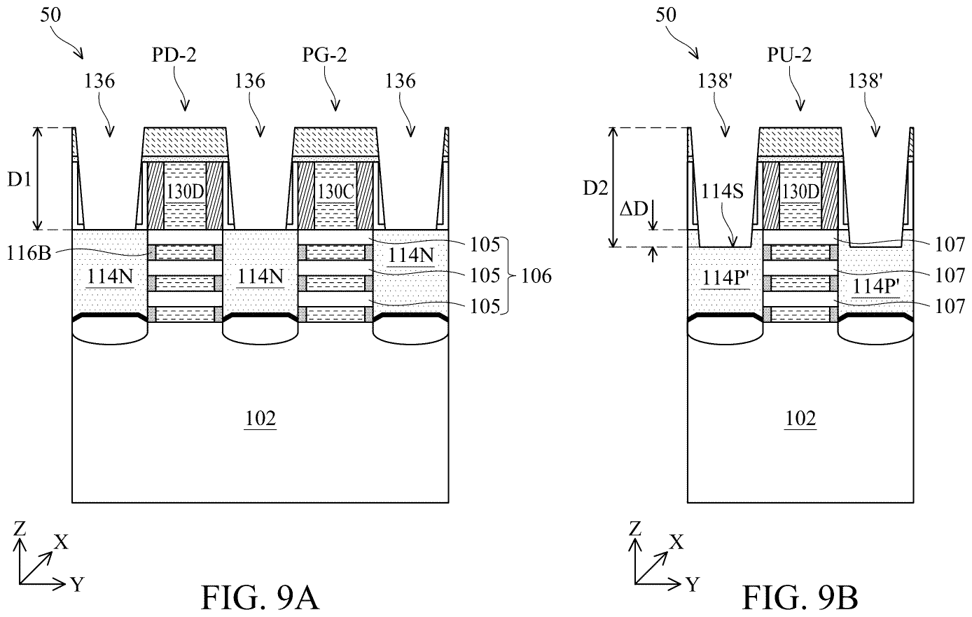

Referring now to FIG. 3 and 7A-9B, method 40 includes a block 43 where first source/drain contact openings 136 (shown in FIG. 9A) and second source/drain contact openings 138′ (shown in FIG. 9B) are formed to extend through the dielectric structure 131 to expose source/drain features 114N of the n-type transistors (e.g., PG-1, PG-2, PD-1, PD-2) and source/drain features 114P of the p-type transistors (e.g., PU-1, PU-2), respectively. In the present disclosure, the second source/drain contact openings 138′ span a depth D2 greater than a depth D1 of the first source/drain contact openings 136.

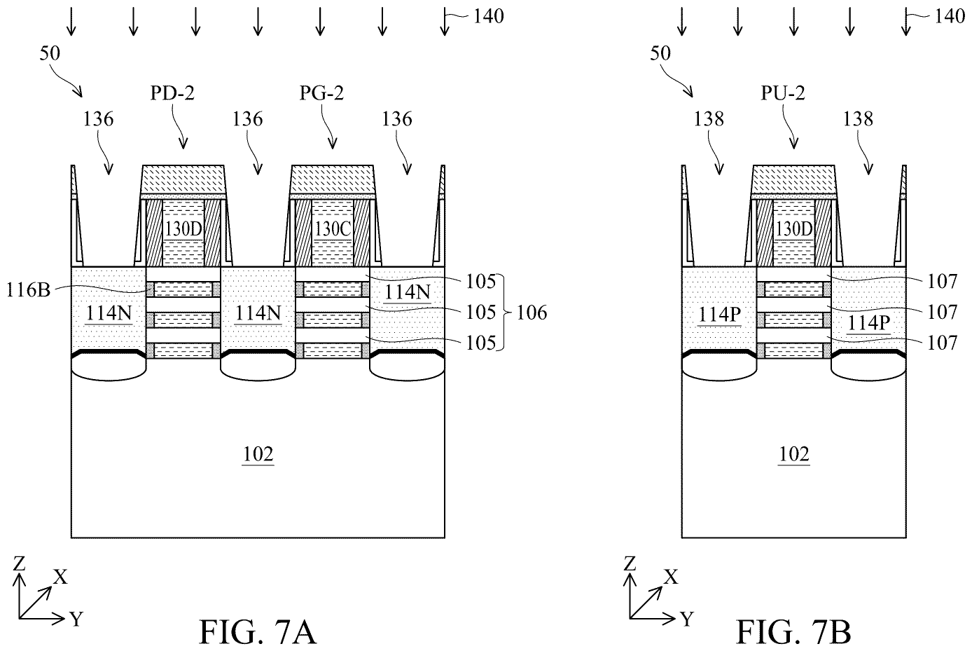

With reference to FIGS. 7A-7B, a masking element (not shown) is formed on the dielectric structure 131. In some embodiments, the masking element may include a hard mask layer and/or a photoresist layer. The masking element is patterned to have first openings disposed directly over the source/drain features 114N and second openings disposed directly over the source/drain features 114P. A first etching process 140 is then performed to remove portions of the dielectric structure 131, the ILD layer 124, and the CESL 122 exposed by the first openings to form the first source/drain contact openings 136. The first etching process 140 also removes portions of the dielectric structure 131, the ILD layer 124, and the CESL 122 exposed by the second openings to form the trenches 138. The first source/drain contact openings 136 and trenches 138 are formed simultaneously. The first source/drain contact openings 136 expose the source/drain features 114N, and the trenches 138 expose the source/drain features 114P. The first etching process 140 may be accurately controlled to stop at the top surface of the source/drain features 114N and 114P. Upon completion of this etching process 140, the first source/drain contact openings 136 and the trenches 138 may have substantially the same depth D1. After performing the etching process 140, the masking element may be selectively removed.

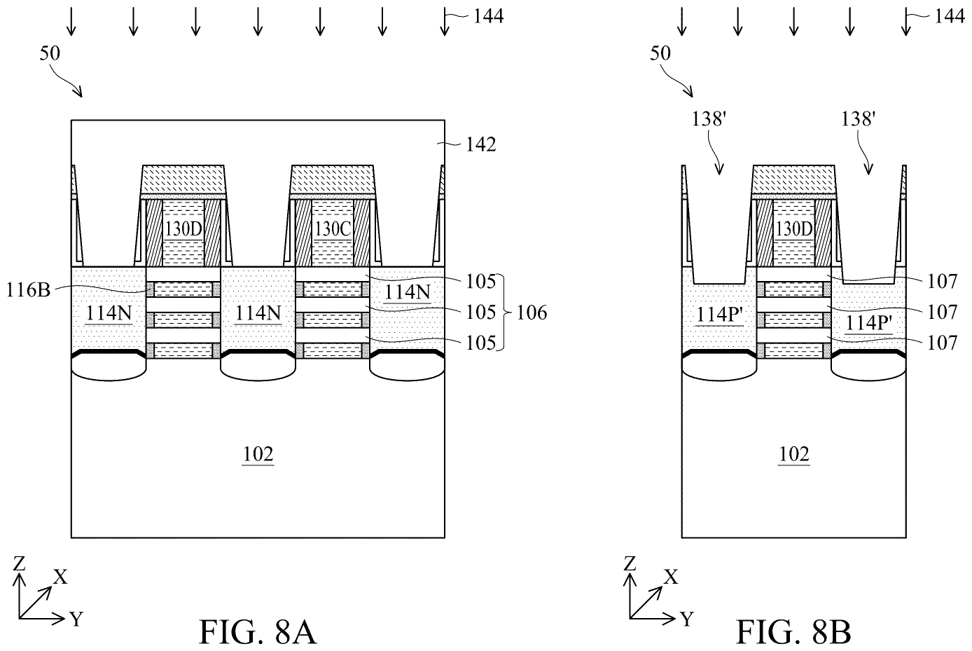

With reference to FIG. 8A-8B, after forming the first source/drain contact openings 136 and the trenches 138, a protection layer 142 (shown in FIG. 8A) is formed to cover the n-type transistors (e.g., PD-1, PD-2, PG-1, PG-2). As represented by FIGS. 8A-8B, the protection layer 142 fills the first source/drain contact openings 136 and does not fill the trenches 138. Then, while using the protection layer 142 and the dielectric structure 131 as an etch mask, an etching process 144 is performed to further vertically extend the trenches 138, thereby forming the second source/drain contact openings 138′. The etching process 144 removes a portion of each of the source/drain features 114P previously exposed by the trenches 138. In an embodiment, the etching process 144 and the etching process 140 have different etchants. For example, the etching process 144 may selectively recess the source/drain features 114P without substantially etching the CESL 122 and the dielectric structure 131.

With reference to FIGS. 9A-9B, the protection layer 142 may be selectively removed after forming the second source/drain contact openings 138′. The second source/drain contact openings 138′ span a depth D2 greater than the depth D1 of the first source/drain contact openings 136. A depth difference ΔD of the second source/drain contact openings 138′ and the first source/drain contact openings 136 may be controlled by adjusting a duration of the etching process 144. In an embodiment, the depth difference ΔD is greater than a thickness of the channel layer 107. In an embodiment, a portion 114S of a top surface (“the exposed surface 114S”) of the recessed source/drain feature 114P is below a bottom surface of a topmost channel layer of the channel layers 107. The recessed source/drain feature 114P after the performing of the etching process 144 may be referred to as the source/drain feature 114P′. Reducing a volume of the source/drain features of the pull-up transistors may induce a non-uniform distribution of current density across the channel layers 107 of the pull-up transistors. For example, a current density across a topmost one of the channel layers 107 will be less than a current density across any other channel layers 107 (e.g., the bottommost one of the channel layers 107). Thus, the saturation current Idₛₐₜ of pull-up transistors in SRAM cell 20B may be reduced, and the write margin of the SRAM cell 20B may be improved. Write margin limits the minimum operable power supply voltage (VCCmin). Improving the write margin may also improve the minimum operable power supply voltage (VCCmin). In addition, the removal of portions of the source/drain features 114P can also advantageously reduce the extent and/or amount of p-type dopants (e.g., boron) from being diffused from the source/drain features 114P′ into the substrate 102, thereby alleviating sub-threshold leakage.

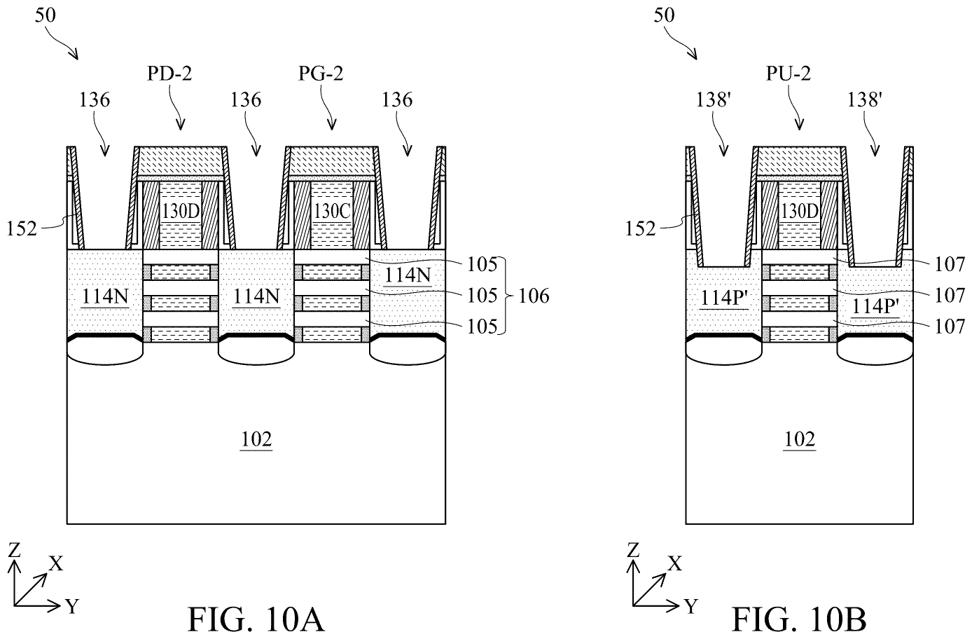

Referring now to FIG. 3 and 10A-10B, method 40 includes a block 44 where dielectric liners 152 are formed in the first source/drain contact openings 136 and the second source/drain contact openings 138′. After the formation of the first source/drain contact openings 136 and the second source/drain contact openings 138′, in some embodiments, a dielectric barrier layer is conformally deposited over the substrate 102, including in the first source/drain contact openings 136 and the second source/drain contact openings 138′. The dielectric barrier layer is then etched back to only cover sidewalls of the first source/drain contact openings 136 and the second source/drain contact openings 138′ and expose the source/drain features 114N and the source/drain features 114P′. The etched back dielectric barrier layer may be referred to as dielectric liners 152. In some embodiments, the dielectric liners 152 may include silicon nitride or other suitable materials. Since the second source/drain contact openings 138′ are deeper than the first source/drain contact openings 136, the dielectric liners 152 formed in the second source/drain contact openings 138′ have a height greater than a height of the dielectric liners 152 formed in the first source/drain contact openings 136. For example, the dielectric liners 152 formed in the second source/drain contact openings 138′ extend below the bottom surface of the topmost one of the channel layers 107, while the dielectric liners 152 formed in the first source/drain contact openings 136 are disposed over the topmost one of the channel layers 105. In some other embodiments, the dielectric liners 152 are optional.

Referring now to FIG. 3 and 11A-11B, method 40 includes a block 45 where first silicide layers 154 are formed in the first source/drain contact openings 136, and second silicide layers 156 are formed in the second source/drain contact openings 138′. After forming the dielectric liners 152, a first silicide layer 154 is formed on the exposed surface of the source/drain feature 114N to reduce a contact resistance between the source/drain feature 114N and the source/drain contact 158 thereover, and a second silicide layer 156 is formed on the exposed surface 114S of the source/drain feature 114P′ to reduce a contact resistance between the source/drain feature 114P′ and the source/drain contact 160 thereover. To form the first and second silicide layers 154 and 156, a metal layer (not explicitly shown) is deposited over the top surface of the substrate 102 and an anneal process is performed to bring about silicidation reaction between the metal layer and the source/drain features 114N and 114P′. Suitable metal layer may include titanium, tantalum, nickel, cobalt, or tungsten. Excessive metal layer that does not form the first and second silicide layers 154 and 156 may be removed. In this embodiment, the second silicide layer 156 is disposed below the first silicide layer 154.

Still referring to FIG. 3 and 11A-11B, method 40 includes a block 46 where first source/drain contacts 158 and second source/drain contacts 160 are formed in the first source/drain contact openings 136 and second source/drain contact openings 138′, respectively. The first source/drain contacts 158 include the first source/drain contacts 158a, 158b, and 158c shown in FIG. 11A, and the second source/drain contacts 160 include the second source/drain contacts 160a and 160b. In an exemplary process, a conductive layer is deposited over the substrate 102, including in the first source/drain contact openings 136 and second source/drain contact openings 138′ and on the silicide layers 154 and 156. The conductive layer may include aluminum (Al), copper (Cu), tungsten (W), cobalt (Co), ruthenium (Ru), or molybdenum (Mo) or other suitable materials and may be formed by any suitable deposition processes (e.g., CVD). In some embodiments, before forming the conductive layer, a conductive barrier layer (e.g., Ti, Ta, TiN, TaN, other suitable materials, or combinations thereof) may be conformally deposited over the substrate 102, include in the first source/drain contact openings 136 and second source/drain contact openings 138′. A planarization process, such as a chemical mechanical polish (CMP) process, may be then performed to remove excess portions of the conductive layer (and the conductive barrier layer, if any) to form the first source/drain contacts 158 in the first source/drain contact openings 136 and the second source/drain contacts 160 in the second source/drain contact openings 138′. After the performing of the planarization process, top surfaces of the first and second source/drain contacts 158 and 160 are coplanar. The second source/drain contacts 160 have a depth D2′ greater than a depth D1′ of the first source/drain contacts 158. A depth difference between the depth D1′ and the depth D2′ are substantially equal to the depth difference ΔD. In an embodiment, a bottom surface of the source/drain contact 160 is below a bottom surface of the first source/drain contact 158 and the bottom surface of the topmost one of the channel layers 107.

FIG. 12 depicts a fragmentary layout of the intermediate structure 50 including the SRAM cell 20B and the first and second source/drain contacts 158 and 160. It is noted that some features (e.g., gate vias, source/drain vias) are omitted for reason of simplicity. Drain of the PD-1 and drain of the PU-1 are electrically connected by a continuous source/drain contact 162. Drain of the PD-2 and drain of the PU-2 are electrically connected by another continuous source/drain contact 162. The first source/drain contact 158b and the second source/drain contact 160b are portions of the continuous source/drain contact 162. By forming first and second source/drain contacts having different depths, write margin of the SRAM cell 20B may be improved.

Referring now to FIG. 3, 11A-11B, and 12, method 40 includes a block 47 where further processes are performed. Such further processes may include forming other features such as gate vias (e.g., gate vias 190 and 192 shown in FIG. 12), butted contacts (e.g., butted contacts 194 and 196), source/drain vias over the source/drain contacts, and an interconnect structure over the substrate 102. In some embodiments, the interconnect structure may include multiple intermetal dielectric (IMD) layers and multiple metal lines or contact vias in each of the IMD layers. In some instances, the IMD layers and the ILD layer 124 may share similar composition. The metal lines and contact vias in each IMD layer may be formed of metal, such as aluminum, tungsten, ruthenium, or copper. In some embodiments, the metal lines and contact vias may be lined by a barrier layer (e.g., Ti, Ta, TiN, TaN, other suitable materials, or combinations thereof) to reduce electro-migration.

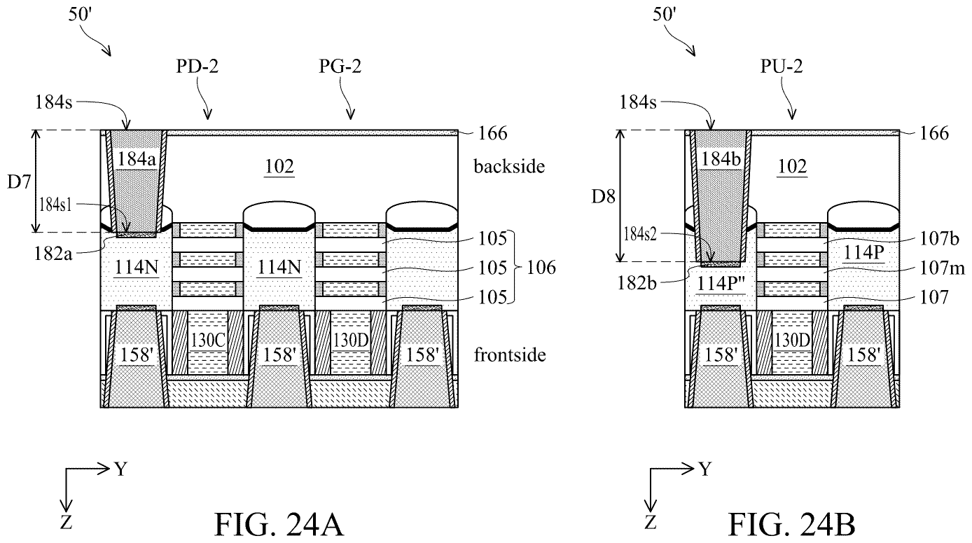

In the above embodiments, frontside source/drain contacts (e.g., the first source/drain contacts 158 and the second source/drain contacts 160) having different depths are be formed to electrically couple corresponding source/drain features of the transistors to corresponding voltages (e.g., Vdd or Vss). In another embodiment depicted below, another method 40′ is described to form backside vias (e.g., backside vias 184a and 184b shown in FIGS. 24A-24B) with different depths to electrically couple corresponding source/drain features of the transistors to corresponding voltages (e.g., Vdd or Vss).

Referring to FIG. 13 and 14A-14B, method 40′ includes the block 41 where an intermediate structure 50′ is received. The intermediate structure 50′ received at block 41 is substantially the same as the intermediate structure 50 described with reference to FIGS. 4 and 5A-5B, and repeated description is omitted for reason of simplicity.

Referring to FIG. 13 and 14A-14B, method 40′ includes a block 42′ where source/drain contacts 158′ are formed over the substrate 202. In an exemplary process, the dielectric structure 131 is formed over the substrate 102. First and second source/drain contact openings are then formed to extend through the dielectric structure 131 to expose source/drain features 114N of the n-type transistors (e.g., PG-1, PG-2, PD-1, PD-2) and source/drain features 114P of the p-type transistors (e.g., PD-1, PD-2), respectively. The first source/drain contact openings may be substantially the same as the first source/drain contact openings 136 and the second source/drain contact openings may be substantially the same as the trenches 138 described above with reference to FIGS. 7A-7B. In an embodiment, the first source/drain contact openings exposing the source/drain features 114N and the second source/drain contact openings exposing the source/drain features 114P have substantially the same depth D1. After forming the first and second source/drain contact openings, dielectric liners 152′, silicide layers 154′, and source/drain contacts 158′ are formed in the first and second source/drain contact openings. The formations and compositions of the dielectric liners 152′, silicide layers 154′, and source/drain contacts 158′ are similar to corresponding dielectric liners 152, silicide layers 154, and source/drain contacts 158 described above with reference to FIGS. 10A-11B, and repeated description is omitted for reason of simplicity. Since the source/drain contacts 158′ are formed over the front side of the source/drain features, the source/drain contacts 158′ may be referred to as frontside source/drain contacts 158′. In this illustrated embodiment, the frontside source/drain contacts 158′ are formed directly over both source and drain of the pull-down transistors (e.g., PD-2) and both source and drain of the pull-up transistors (e.g., PU-2). In another alternative embodiment, since backside vias will be formed under the source of the pull-down transistor (e.g., PD-2) and source of the pull-up transistor (e.g., PU-2), the frontside source/drain contact formed over the source of the pull-down transistor (e.g., PD-2) and the frontside source/drain contact formed over the source of the pull-up transistor (e.g., PU-2) may be omitted.

After forming the frontside source/drain contacts 158′, various features such as gate vias, source/drain vias, and a multi-layer interconnect structure (not shown) may be formed over the front side of the transistors. The multi-layer interconnect structure may include a number of conductive features (e.g., metal lines and/or vias) configured to interconnect various components of the SRAM cells with additional features to ensure the proper performance of the IC structure 10. The conductive features of the multi-layer interconnect structure may be disposed in and/or separated by intermetal dielectric (IMD) layers. The conductive features of the multi-layer interconnect structure may include metal lines/contacts formed on or over the frontside source/drain vias or the gate vias. Each conductive feature of the multi-layer interconnect structure may be formed of metal, such as aluminum, tungsten, ruthenium, or copper. Each IMD layer may include a low-k dielectric material, silicon oxide, other suitable dielectric materials, or combinations thereof, and may be formed by spin-on-glass, flowable CVD (FCVD), other suitable methods, or combinations thereof.

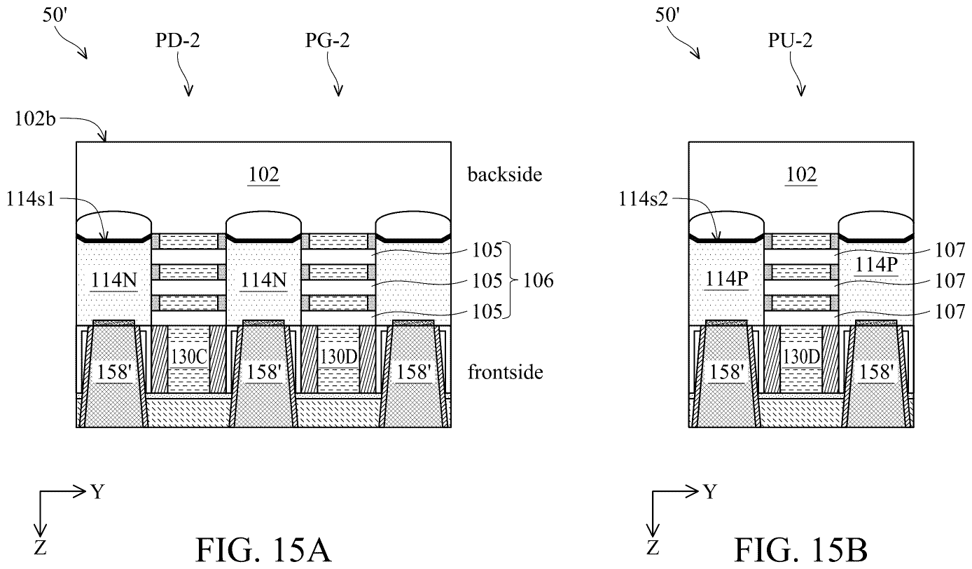

Referring to FIG. 13 and 15A-15B, method 40′ includes a block 43′ where the intermediate structure 50′ is flipped over. After forming the multi-layer interconnect structure over the front side of the transistors, a carrier substrate may be bonded to the multi-layer interconnect structure, and the intermediate structure 50′ is then flipped over. In some embodiments, the carrier substrate may be bonded to the intermediate structure 50′ by fusion bonding, by use of an adhesion layer, or a combination thereof. In some instances, the carrier substrate may include semiconductor materials (such as silicon), sapphire, glass, polymeric materials, or other suitable materials. In some embodiments, a thinning process may be performed to thin the substrate 102 from its backside to reduce a total thickness of the intermediate structure 50′. The thinning process may include a mechanical grinding process and/or a chemical thinning process. For example, a substantial amount of substrate material may be removed from the substrate 102 during a mechanical grinding process. After the thinning down process, the substrate 102 has a bottom surface 102b. For ease of description, the positional relationships (e.g., over, below, above, under) of features of the flipped-over intermediate structure 50′ will be described in accordance with the figures. For example, as shown in FIGS. 15A-15B, after the intermediate structure 50′ is flipped over, the substrate 102 is disposed over the channel layers 105 and 107. Bottom surfaces 114s1 of the source/drain features 114N and bottom surfaces 114s2 of source/drain features 114P are now disposed over their top surfaces.

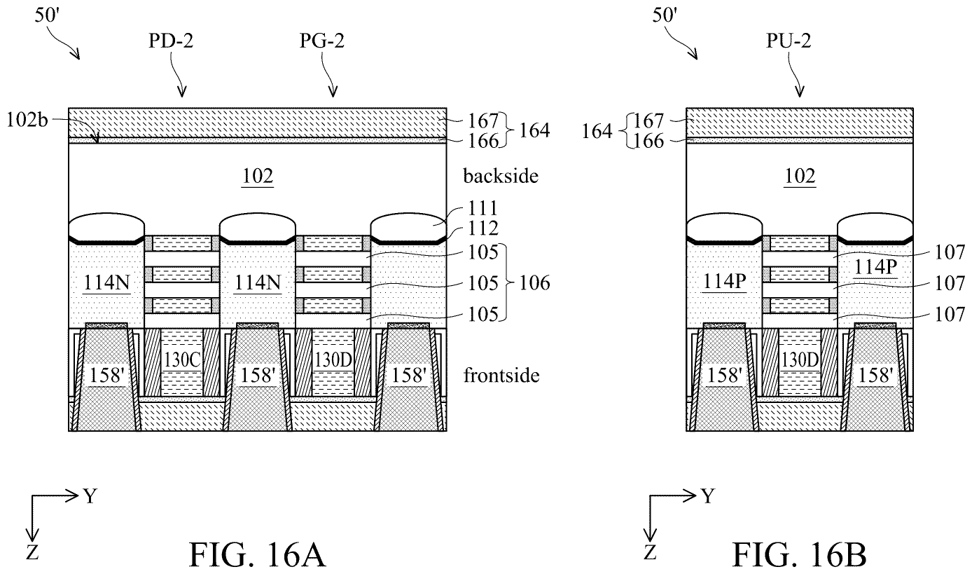

Referring to FIG. 13 and 16A-16B, method 40′ includes a block 44′ where a dielectric structure 164 is formed over the back side of the intermediate structure 50′. In the present embodiment, to provide an end point for a subsequent planarization process, the dielectric structure 164 includes a first layer 166 and a second layer 167 having a material composition different than the first layer 166. In an embodiment, the first layer 166 includes a nitride layer (e.g., silicon nitride), and the second layer 167 includes an oxide layer (e.g., silicon oxide).

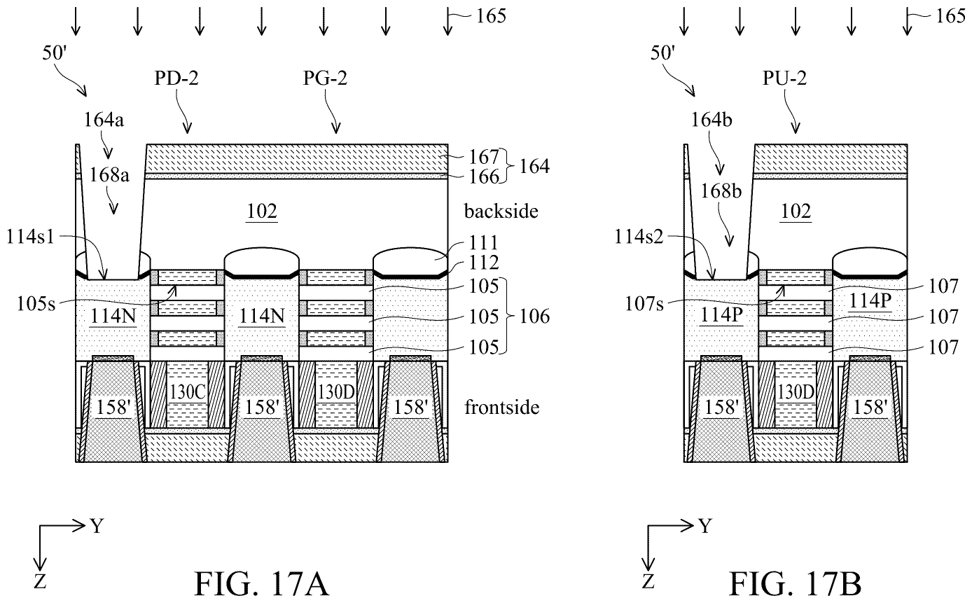

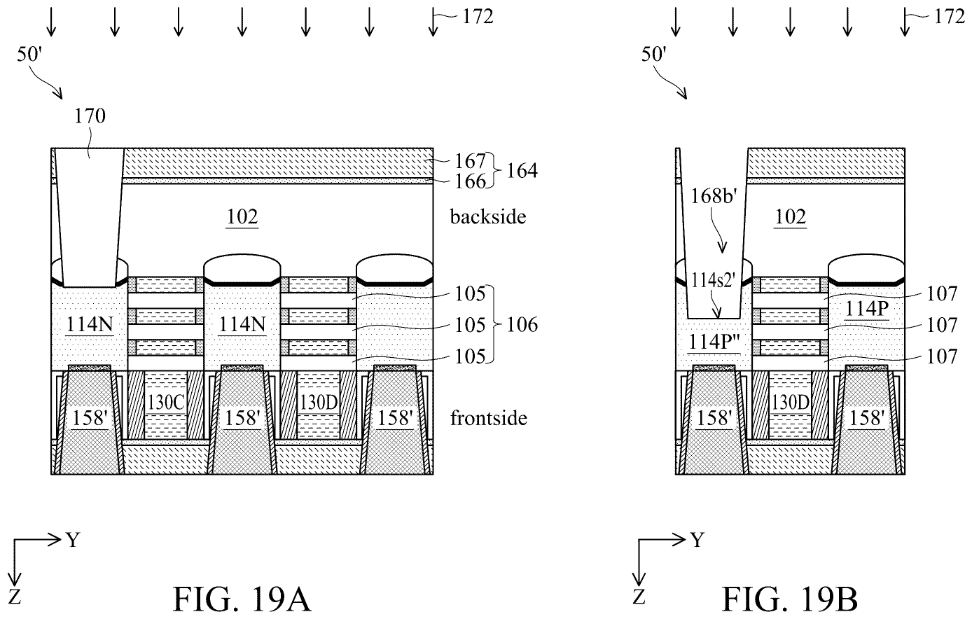

Referring to FIGS. 13 and 17A-22B, method 40′ includes a block 45′ where a first backside via opening 168a (shown in FIG. 17A) is formed to expose a bottom surface 114s1 of the source/drain feature 114N and a second backside via opening 168b′ (shown in FIG. 19B) is formed to expose a bottom surface 114s2′ of the source/drain feature 114P. The second backside via opening 168b′ spans a depth greater than a depth of the first backside via opening 168a. Two exemplary methods may be implemented to form the first backside via opening 168a and the second backside via opening 168b′.

With reference to FIGS. 17A-20B, a first method of forming the first backside via opening 168a and the second backside via opening 168b′ will be described. Referring to FIGS. 17A-17B, the dielectric structure 164 is patterned to form an opening 164a directly over the backside of the source of the pull-down transistor PD-2 and an opening 164b directly over the backside of the source of the pull-up transistor PU-2. In this embodiment, the openings 164a and 164b are formed simultaneously. It is understood that the dielectric structure 164 can also be patterned to form openings directly over the backside of the source of the pull-down transistor PD-1 and the backside of the source of the pull-up transistor PU-1. While using the patterned dielectric structure 164 as an etch mask, a first etching process 165 is performed to form the first backside via opening 168a disposed under the opening 164a and further form a trench 168b disposed under the opening 164b. The first backside via opening 168a extends through the substrate 102, the undoped semiconductor layer 111, the insulation layer 112 and exposes the bottom surface 114s1 of the source (e.g., the left one of the source/drain features 114N shown in FIG. 17A) of the pull-down transistor PD-2. The trench 168b extends through the substrate 102, undoped semiconductor layer 111, the insulation layer 112 and exposes the bottom surface 114s2 of the source (e.g., the left one of the source/drain features 114P shown in FIG. 17B) of the pull-up transistor PU-2. In an embodiment, after the performing of the first etching process 165, the first backside via opening 168a and the trench 168b have a substantially the same depth. As indicated by the dashed line, the bottom surface 114s1 may be above a bottom surface 105s of the bottommost channel layer 105, and the bottom surface 114s2 may be above a bottom surface 107s of the bottommost channel layer 107. It is understood that, if the intermediate structure 50′ is flipped back, the bottom surface 114s1 is below the bottom surface 105s of the bottommost channel layer 105, and the bottom surface 114s2 is below the bottom surface 107s of the bottommost channel layer 107.

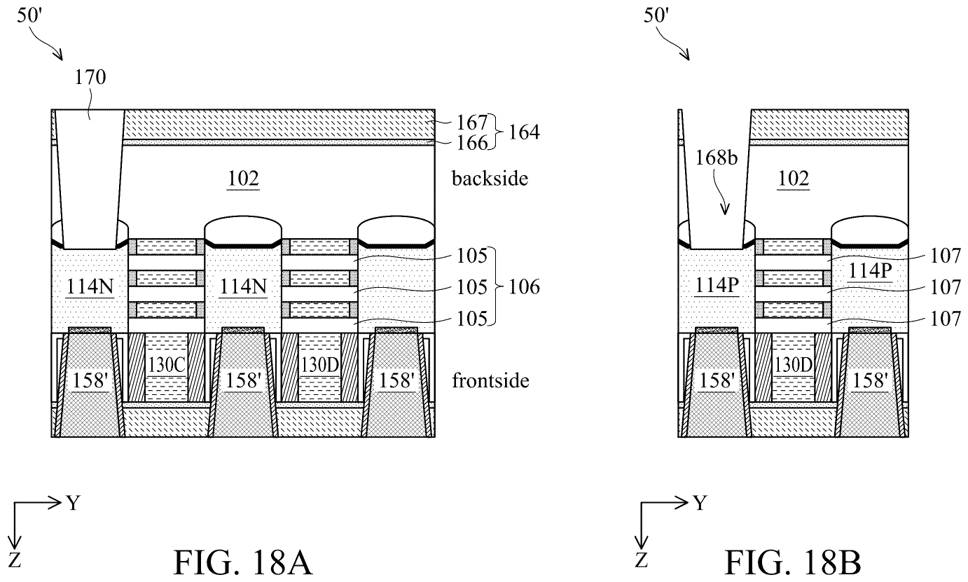

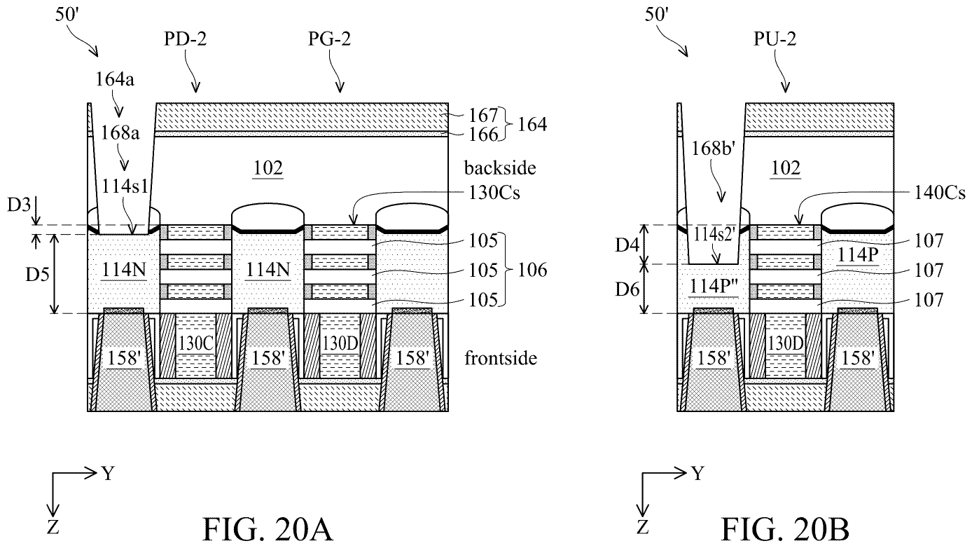

Referring to FIGS. 18A-18B, after forming the first backside via opening 168a and the trench 168b, a protection layer 170 is formed over the backside of the n-type transistors (e.g., PD-1, PD-2, PG-1, PG-2). As represented by FIGS. 18A-18B, the protection layer 170 fills the first backside via opening 168a and does not fill the trench 168b. Then, as illustrated by FIGS. 19A-19B, while using the protection layer 170 and the patterned dielectric structure 164 as an etch mask, a second etching process 172 is performed to further vertically extend the trench 168b, thereby forming the second backside via opening 168b′. The second etching process 172 removes a portion of the source/drain feature 114P from its back. In an embodiment, the second etching process 172 and the first etching process 165 have different etchants. For example, the etching process 172 may selectively recess the source/drain feature 114P without substantially etching the dielectric structure 164. The recessed source/drain feature 114P after the performing of the etching process 172 may be referred to as the source/drain feature 114P″. As shown in FIGS. 20A-20B, after forming the second backside via opening 168b′, the protection layer 170 may be selectively removed.

Due to the selective performing of the second etching process 172, the second backside via opening 168b′ spans a depth greater than the depth of the first backside via opening 168a. A depth difference ΔD′ of the second backside via opening 168b′ and the first backside via opening 168a may be controlled by adjusting a duration of the etching process 172. In an embodiment, the depth difference ΔD′ is greater than a thickness of the channel layer 107. As illustrated by FIGS. 20A-20B, the second backside via opening 168b′ now exposes a bottom surface 114s2′ of the source/drain feature 114P″. The bottom surface 114s2′ is below the bottom surface 114s1. A distance between a bottommost surface 130Cs of the gate structure 130C and the exposed bottom surface 114s1 is denoted as D3, and a distance between a bottommost surface 140Ds of the gate structure 130D and the exposed bottom surface 114s2′ is denoted as D4. D4 is greater than D3. In an embodiment, a ratio of the distance D3 to the distance D4 is in a range between about 0.6 and about 0.9. If the ratio is greater than 0.9, then the volume of the portion of the source/drain feature 114P removed by the etching process 172 may not be large enough to achieve satisfactory performance difference between the pull-down transistors and the pull-up transistors and thus cannot improve the write margin significantly. If the ratio is less than 0.6, parasitic resistance associated with the resulted source/drain feature 114P″ may be too large, disadvantageously affecting the performance of the transistor itself. The depth difference ΔD′ is substantially equal to the difference between the depth D3 and the depth D4 (i.e., ΔD′=D4−D3).

A distance between a top surface of the source of the pull-down transistor PD-2 and the exposed bottom surface 114s1 is denoted as D5, and a distance between a top surface of the source of the pull-up transistor PU-2 and the exposed bottom surface 114s2″ is denoted as D6. D5 is greater than D6. In an embodiment, a ratio of the distance D5 to the distance D6 is in a range between about 1.1 and about 1.4. If the ratio is less than 1.1, then the volume of the portion of the source/drain feature 114P removed by the etching process 172 may not be large enough to achieve satisfactory performance difference between the pull-down transistors and the pull-up transistors and thus cannot improve the write margin significantly. If the ratio is greater than 1.4, parasitic resistance associated with the resulted source/drain feature 114P″ may be too large, disadvantageously affecting the performance of the transistor itself.

As described above, reducing a volume of the source feature of the pull-up transistors may induce a non-uniform distribution of current density across the channel layers 107 of the pull-up transistors. For example, in this embodiment, a current density across the bottommost channel layer 107 will be less than a current density across any other channel layers 107 (e.g., the top channel layer 107). Thus, the saturation current Idₛₐₜ of pull-up transistors in SRAM cell 20B may be reduced, and the write margin of the SRAM cell 20B may be improved. In addition, the removal of portions of the source/drain features 114P can also advantageously reduce the extent and/or amount of p-type dopants (e.g., boron) from being diffused from the source/drain features 114P″ into the substrate 102, thereby alleviating sub-threshold leakage. It is noted that, different from the pull-up transistor in the intermediate structure 50 which includes the source/drain features 114P′, the pull-up transistor in the intermediate structure 50′ includes the source 114P″ and the drain 114P. That is, a volume of the drain (e.g., 114P shown in FIG. 20B) of the pull-up transistor in the intermediate structure 50′ is greater than a volume of the source (e.g., 114″ shown in FIG. 20B) of the pull-up transistor in the intermediate structure 50′.

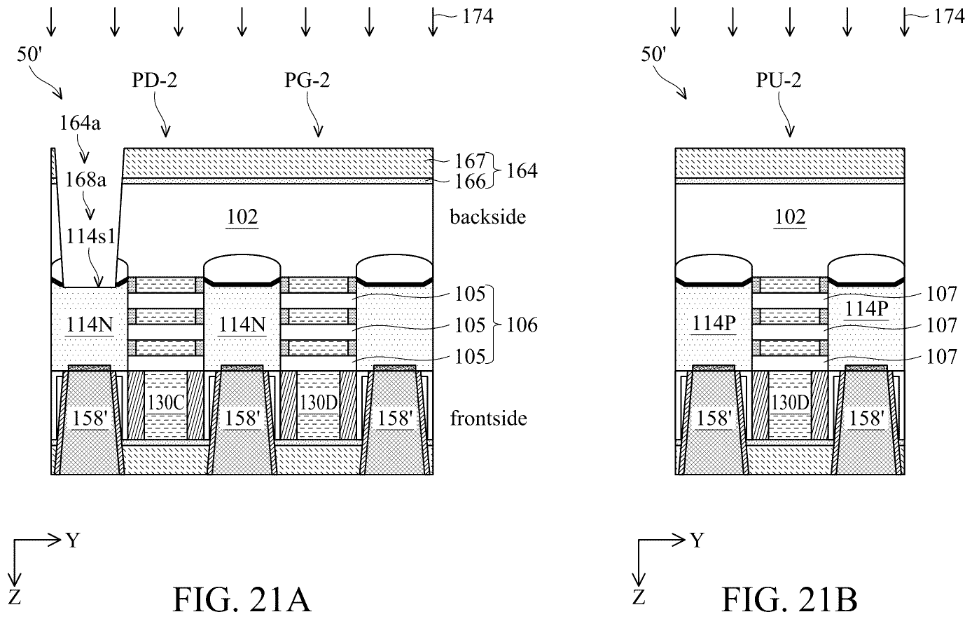

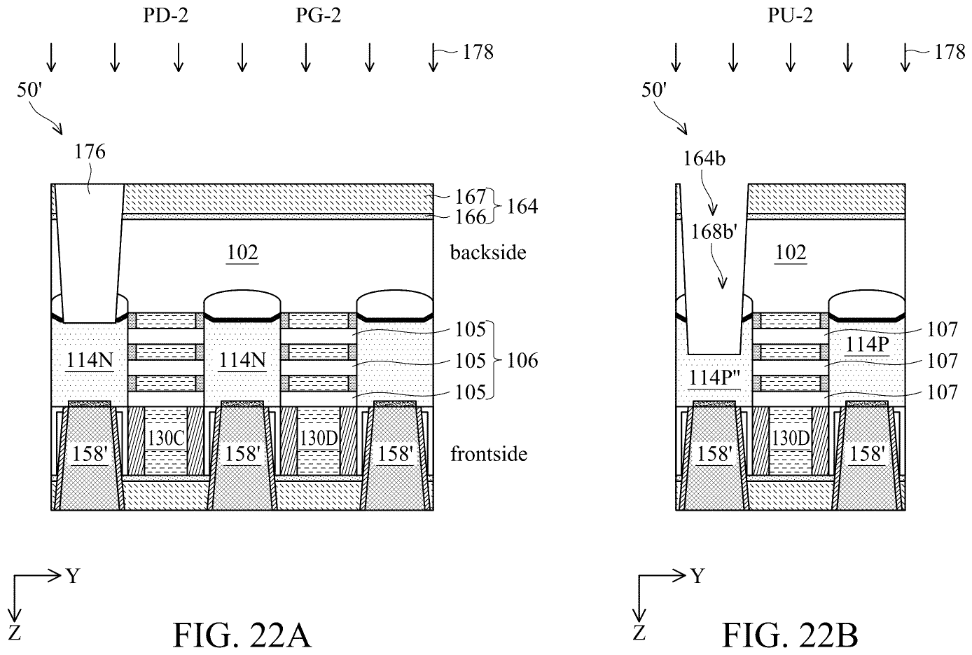

With reference to FIGS. 21A-22B, a second method of forming the first backside via opening 168a and the second backside via opening 168b′ will be described. According to this second method, the openings 164a and 164b are formed in a sequential order. Referring to FIGS. 21A-21B, the dielectric structure 164 is patterned to form the opening 164a directly over the backside of the source of the pull-down transistor PD-2. It is understood that the dielectric structure 164 can also be patterned to form openings directly over the backside of the source of the pull-down transistor PD-1. In this embodiment, the patterned dielectric structure 164 has not been patterned to include the openings 164b yet. While using the patterned dielectric structure 164 as an etch mask, a third etching process 174 is performed to form the first backside via opening 168a disposed under the opening 164a. Then, a protection layer 176 is formed to cover the exposed surface 114s1 of the source/drain feature 114N. As represented by FIGS. 22A-22B, the protection layer 176 fills the first backside via opening 168a. It is understood that the profile of the protection layers (e.g., the protection layers 142, 170, 176) is just an example and is not intended to be limiting. The patterned dielectric structure 164 is then patterned to form the opening 164b. The opening 164b is directly over the backside of the source (e.g., the left one of the source/drain features 114P) of the pull-up transistor PU-2. It is understood that the dielectric structure 164 can also be patterned to form openings directly over the backside of the source of the pull-up transistor PU-1. With the protection layer 176 covering the first backside via opening 168a and with the formation of the opening 164b, a fourth etching process 178 is performed to form the second backside via opening 168b′ disposed under the opening 164b. The protection layer 176 may be removed after the formation of the second backside via opening 168b′. In embodiments where the third etching process 174 and the fourth etching process 178 have same configurations (e.g., etchants, temperature), the duration of the fourth etching process 178 is greater than the duration of the third etching process 174, such that the depth of the second backside via opening 168b′ is greater than the depth of the first backside via opening 168a. In some embodiments, the opening 164b is formed prior to the formation of the opening 164a, and the second backside via opening 168b′ is formed prior to the formation of the first backside via opening 168a.

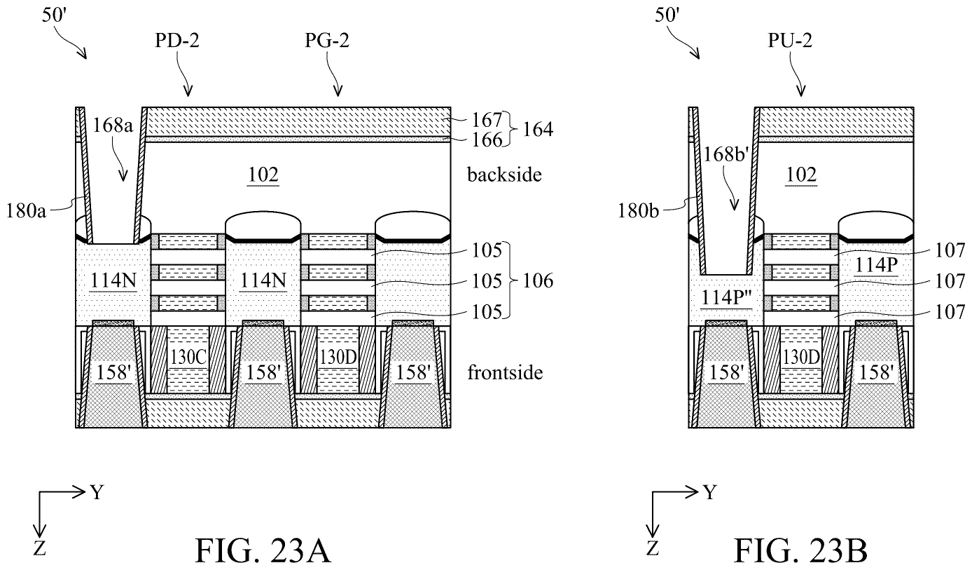

Referring to FIGS. 13 and 23A-23B, method 40′ includes a block 46′ where dielectric liners 180a-180b are formed in the first backside via opening 168a and second backside via opening 168b′. After the formation of the first backside via opening 168a and second backside via opening 168b′, a dielectric barrier layer is conformally deposited over the backside of the substrate 102, including in the first backside via opening 168a and second backside via opening 168b′. The dielectric barrier layer is then etched back to only cover sidewalls of the first backside via opening 168a and second backside via opening 168b′ and expose the bottom surface 114s1 of the source/drain features 114N and the bottom surface 114s2′ of the source/drain features 114P″. The etched back dielectric barrier layer forms the dielectric liner 180a in the first backside via opening 168a and the dielectric liner 180a in the second backside via opening 168b′. In some embodiments, the dielectric liners 180a-180b may include silicon nitride or other suitable materials. The dielectric liner 180b formed in the second backside via opening 168b′ have a height greater than a height of the dielectric liners 180a formed in the first backside via opening 168a.

Referring to FIGS. 13 and 24A-24B, method 40′ includes a block 47′ where a first silicide layer 182a and a second silicide layer 182b are formed in the first backside via opening 168a and the second backside via opening 168b′, respectively. After forming the dielectric liners 180a-180b, a first silicide layer 182a is formed on the exposed bottom surface 114s1 of the source/drain feature 114N, and a second silicide layer 182b is formed on the exposed bottom surface 114s2′ of the source/drain feature 114P″. The composition and formation of the first silicide layer 182a and second silicide layer 182b may be similar to those of the first and second silicide layers 154 and 156, and repeated description is omitted for reason of simplicity. In this embodiment, due to the deeper second backside via opening 168b′, as shown in FIGS. 24A-24B, the second silicide layer 182b is disposed below the first silicide layer 182a.

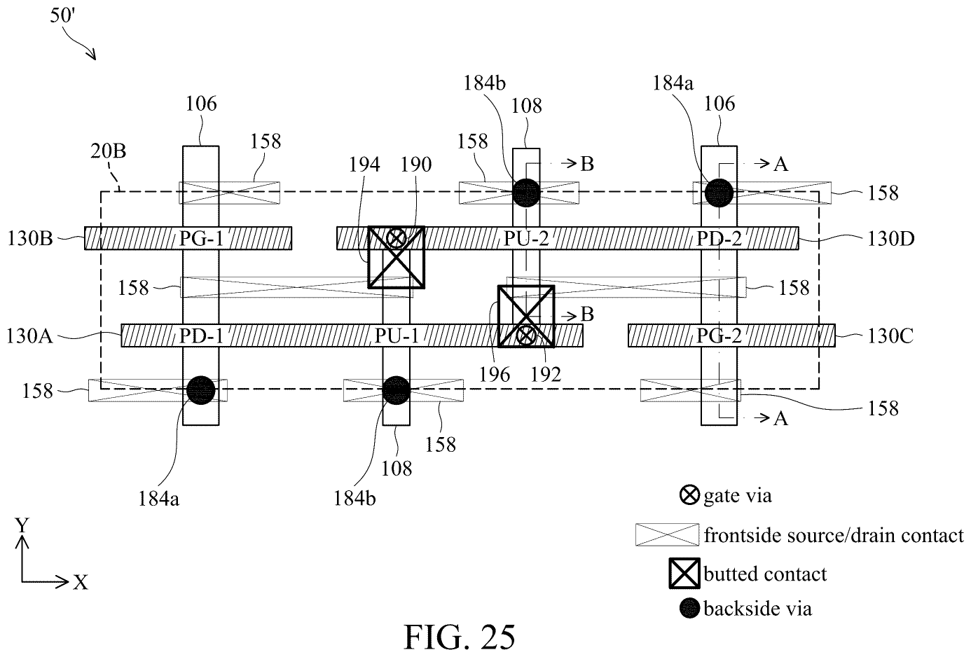

Referring to FIGS. 13, 24A-24B, and 25, method 40′ includes a block 48′ where a first backside via 184a and a second backside via 184b are formed in the first backside via opening 168a and the second backside via opening 168b′, respectively. The formation of the first backside via 184a and the second backside via 184b may include depositing a conductive layer (e.g., aluminum, rhodium, ruthenium, copper, iridium, or tungsten) over the bottom surface of the intermediate structure 50′ to the openings 164a-164b, the first backside via opening 168a, and the second backside via opening 168b′ and performing a planarization process (e.g., chemical mechanical polish (CMP) process) to remove excess materials and the second layer 167. The planarization process stops on the bottom surface of the first layer 166. The first backside via 184a is electrically coupled to the source/drain feature 114N by way of the first silicide layer 182a. The second backside via 184b is electrically coupled to the source/drain feature 114P″ by way of the silicide layer 182b. Bottom surfaces 184s of the first backside via 184a and the second backside via 184b are coplanar with a bottom surface of the first layer 166. A top surface 184s1 of the first backside via 184a is above top surface 184s2 of the second backside via 184b. In an embodiment, the top surface 184s2 is between the bottommost one 107b of the channel layers 107 and the middle one 107m of the channel layers 107. A depth D8 of the second backside via 184b is greater than a depth D7 of the first backside via 184a. A depth difference between the depth D8 and the depth D7 is substantially equal to the depth difference ΔD′. FIG. 25 depicts a fragmentary layout of the structure 50′ including the SRAM cell 20B, the source/drain contacts 158, the first backside via 184a, and the second backside via 184b. It is noted that some features (e.g., gate vias, source/drain vias) are omitted for reason of simplicity.

Referring back to FIG. 13, method 40′ includes a block 49′ where further processes are performed. Such further processes may include forming a backside power rail to electrically couple to the first backside via 184a and the second backside via 184b. The formation of the backside power rail may be similar to the formation of the multi-layer interconnect structure described above, and repeated description is omitted for reason of simplicity.

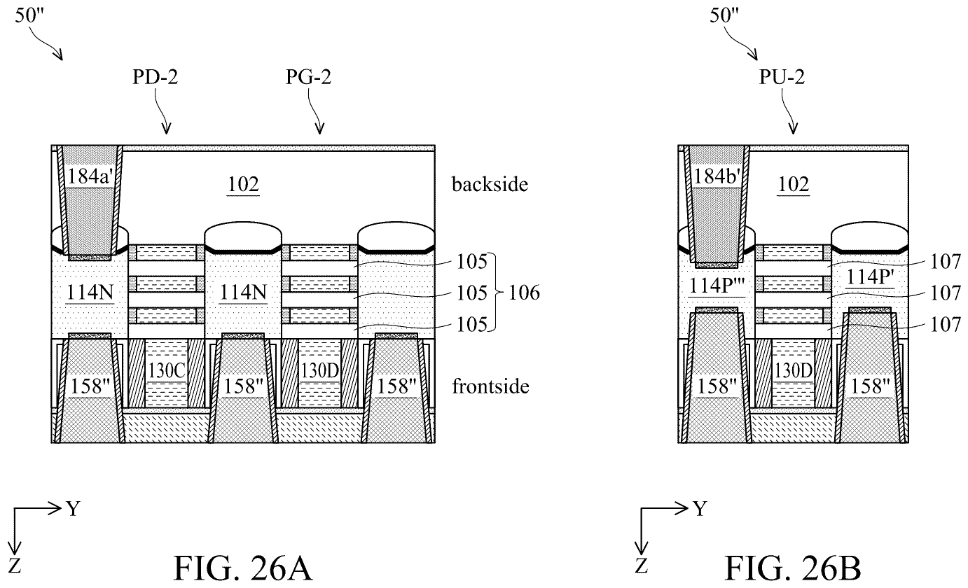

In the above embodiments, the intermediate structure 50 includes the frontside source/drain contacts 158 and 160 having different depths, and the intermediate structure 50′ includes the backside vias 184a and 184b having different depths. FIGS. 26A-26B depicts fragmentary cross-sectional views of another intermediate structure 50″. The intermediate structure 50″ may be similar to the structure 50′, and a layout of the structure 50″ is substantially the same as the structure 50′. One of the differences between the structure 50″ and the structure 50′ includes that, the structure 50″ includes source/drain contacts 158″ and 160″ having different depths, and further includes backside vias 184a′ and 184b′ having different depths. The source/drain contact 158″ and the backside via 184a′ are substantially the same as the source/drain contact 158 and the backside via 184a, respectively. The source/drain contact 160″ may be similar to the source/drain contact 160, and the backside via 184b′ may be similar to the backside via 184b. That is, a depth of the source/drain contact 160″ is greater than a depth of the source/drain contact 158″, and a depth of the backside via 184b′ is greater than a depth of the backside via 184a′. In an embodiment, a difference between a sum of the depth of the source/drain contact 160″ and the depth of backside via 184b′ and a sum of the depth of the source/drain contact 158″ and the depth of backside via 184a′ is substantially equal to the depth difference ΔD′.

Although not intended to be limiting, one or more embodiments of the present disclosure provide many benefits to an IC structure and the formation thereof. For example, the present embodiments provide an array of memory cells, such as SRAM cells, in an IC structure, where each SRAM cell includes n-type GAA transistors, such as pull-down transistors and pass-gate transistors, and p-type GAA transistors, such as pull-up transistors. In the present embodiments, by forming frontside source/drain contacts and/or backside vias having different depths, write margin, VCCmin, and Vmax of the SRAM cell may be improved. In addition, the sub-threshold leakage associated with the pull-up transistors may also be alleviated. It should be noted that even though the embodiments of the present disclosure are described together with the six transistors (6T) single-port SRAM cell, the present disclosure is not limited to this. For example, the present disclosure can be applied to SRAM cells composed of more transistors, such as 7T, 8T, 9T, or 10T, and can be single-port, dual-port, or multi-port, or other types of memory cells. The present disclosure may also be applied to logic circuits or logic cells.

The present disclosure provides for many different embodiments. Semiconductor structures and methods of fabrication thereof are disclosed herein. In one exemplary aspect, the present disclosure is directed to a method. The method includes receiving an intermediate structure comprising an n-type transistor and a p-type transistor, forming a dielectric structure under the n-type transistor and the p-type transistor, forming a first trench and a second trench each extending through the dielectric structure, the first trench exposing a bottom surface of a source/drain feature of the n-type transistor, the second trench exposing a bottom surface of a source/drain feature of the p-type transistor, wherein a depth of the second trench is greater than a depth of the first trench, forming a first silicide layer and a second silicide layer in the first trench and the second trench, respectively, and forming a first backside via and a second backside via in the first trench and the second trench, respectively.

In some embodiments, the p-type transistor may include a plurality of nanostructures and a first gate structure wrapping around and over the plurality of nanostructures, and a top surface of the second backside via is above a top surface of a bottommost nanostructure of the plurality of nanostructures. In some embodiments, the n-type transistor may include an undoped semiconductor layer in a substrate and a dielectric layer disposed between the undoped semiconductor layer and the source/drain feature of the n-type transistor, the first trench extends through the dielectric layer. In some embodiments, the forming of the first trench and the second trench may include patterning the dielectric structure, the patterned dielectric structure comprising a first opening under the source/drain feature of the n-type transistor and a second opening under the source/drain feature of the p-type transistor, performing a first etching step to form the first trench and a groove, the groove exposing the source/drain feature of the p-type transistor, forming a protection layer in the first trench, and performing a second etching step to remove a portion of the source/drain feature of the p-type transistor to vertically extend the groove, thereby forming the second trench. In some embodiments, the method may also include after the forming of the first trench and second trench, forming a first dielectric liner extending along sidewall surfaces of the first trench and a second dielectric liner extending along sidewall surfaces of the second trench, the first and second dielectric liners have different heights. In some embodiments, the intermediate structure may include a memory cell, and the n-type transistor and p-type transistor are portions of the memory cell. In some embodiments, the intermediate structure may also include a first source/drain contact over and electrically coupled to the source/drain feature of the n-type transistor, and a second source/drain contact over and electrically coupled to the source/drain feature of the p-type transistor. In some embodiments, the dielectric structure may include a nitride layer and an oxide layer under the nitride layer, and the forming of the first backside via and second backside via may include depositing a conductive material layer under the dielectric structure and in the first and second trenches, and performing a planarization process, wherein the planarization process removes the oxide layer. In some embodiments, the source/drain feature of the p-type transistor is a first source/drain feature, the p-type transistor includes a second source/drain feature, and after the forming of the first backside via and the second backside via, a volume of the second source/drain feature is greater than a volume of the first source/drain feature. In some embodiments, a top surface of the second silicide layer is above a top surface of the first silicide layer.

In another exemplary aspect, the present disclosure is directed to a method. The method includes forming a memory cell over a substrate, the memory cell comprising a pull-up transistor and a pull-down transistor, forming a dielectric structure over the pull-up transistor and the pull-down transistor, after the forming of the dielectric structure, reducing a volume of a source/drain feature of the pull-up transistor, and after the reducing of the volume, forming a first conductive feature electrically coupled to a source/drain feature of the pull-down transistor and a second conductive feature electrically coupled to the source/drain feature of the pull-up transistor, wherein the first conductive feature and the second conductive feature have different depths.

In some embodiments, the reducing of the volume of the source/drain feature of the pull-up transistor may include forming an opening exposing the source/drain feature of the pull-up transistor, and performing an etching process to remove a portion of the source/drain feature of the pull-up transistor. In some embodiments, the opening exposes a bottom surface of the source/drain feature of the pull-up transistor. In some embodiments, the method may also include forming a first dielectric liner providing isolation between the first conductive feature and the substrate, and forming a second dielectric liner providing isolation between the second conductive feature and the substrate. In some embodiments, the pull-up transistor is a p-type transistor and may include a plurality of nanostructures coupled to the source/drain feature of the pull-up transistor. In some embodiments, the second conductive feature is disposed under the source/drain feature of the pull-up transistor, and a top surface of the second conductive feature is above a top surface of a bottommost nanostructure of the plurality of nanostructures.

In yet another exemplary aspect, the present disclosure is directed to a semiconductor structure. The semiconductor structure includes a first transistor comprising a first source/drain feature, a second transistor comprising a second source/drain feature, a first conductive feature disposed under and electrically coupled to the first source/drain feature, a second conductive feature disposed under and electrically coupled to the second source/drain feature, the first conductive feature and the second conductive feature have different depths.

In some embodiments, the first transistor is a pull-up transistor of a memory cell, the second transistor is a pull-down transistor of the memory cell, and a depth of the first conductive feature is greater than a depth of the second conductive feature. In some embodiments, the first transistor may include a plurality of nanostructures coupled to the first source/drain feature, and a top surface of the first conductive feature is above a top surface of a bottommost nanostructure of the plurality of nanostructures. In some embodiments, the semiconductor structure may also include a dielectric liner extending along sidewall surfaces of the first conductive feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving an intermediate structure comprising an n-type transistor and a p-type transistor;
forming a dielectric structure under the n-type transistor and the p-type transistor;
forming a first trench and a second trench each extending through the dielectric structure, the first trench exposing a bottom surface of a source/drain feature of the n-type transistor, the second trench exposing a bottom surface of a source/drain feature of the p-type transistor, wherein a depth of the second trench is greater than a depth of the first trench;
forming a first silicide layer and a second silicide layer in the first trench and the second trench, respectively; and
forming a first backside via and a second backside via in the first trench and the second trench, respectively.

2. The method of claim 1, wherein the p-type transistor comprises a plurality of nanostructures and a first gate structure wrapping around and over the plurality of nanostructures, wherein a top surface of the second backside via is above a top surface of a bottommost nanostructure of the plurality of nanostructures.

3. The method of claim 1, wherein the n-type transistor comprises an undoped semiconductor layer in a substrate and a dielectric layer disposed between the undoped semiconductor layer and the source/drain feature of the n-type transistor, wherein the first trench extends through the dielectric layer.

4. The method of claim 1, wherein the forming of the first trench and the second trench comprises:
patterning the dielectric structure, the patterned dielectric structure comprising a first opening under the source/drain feature of the n-type transistor and a second opening under the source/drain feature of the p-type transistor;
performing a first etching step to form the first trench and a groove, the groove exposing the source/drain feature of the p-type transistor;
forming a protection layer in the first trench; and
performing a second etching step to remove a portion of the source/drain feature of the p-type transistor to vertically extend the groove, thereby forming the second trench.

5. The method of claim 1, further comprising:
after the forming of the first trench and second trench, forming a first dielectric liner extending along sidewall surfaces of the first trench and a second dielectric liner extending along sidewall surfaces of the second trench,
wherein the first and second dielectric liners have different heights.

6. The method of claim 1, wherein the intermediate structure comprises a memory cell, and the n-type transistor and p-type transistor are portions of the memory cell.

7. The method of claim 1, wherein the intermediate structure further comprises:
a first source/drain contact over and electrically coupled to the source/drain feature of the n-type transistor; and
a second source/drain contact over and electrically coupled to the source/drain feature of the p-type transistor.

8. The method of claim 1, wherein the dielectric structure comprises a nitride layer and an oxide layer under the nitride layer, and the forming of the first backside via and second backside via comprises:
depositing a conductive material layer under the dielectric structure and in the first and second trenches; and
performing a planarization process, wherein the planarization process removes the oxide layer.

9. The method of claim 1, wherein, the source/drain feature of the p-type transistor is a first source/drain feature, the p-type transistor comprises a second source/drain feature, and after the forming of the first backside via and the second backside via, a volume of the second source/drain feature is greater than a volume of the first source/drain feature.

10. The method of claim 1, wherein a top surface of the second silicide layer is above a top surface of the first silicide layer.

11. A method, comprising:
forming a memory cell over a substrate, the memory cell comprising a pull-up transistor and a pull-down transistor;
forming a dielectric structure over the pull-up transistor and the pull-down transistor;
after the forming of the dielectric structure, reducing a volume of a source/drain feature of the pull-up transistor; and
after the reducing of the volume, forming a first conductive feature electrically coupled to a source/drain feature of the pull-down transistor and a second conductive feature electrically coupled to the source/drain feature of the pull-up transistor, wherein the first conductive feature and the second conductive feature have different depths.

12. The method of claim 11, wherein the reducing of the volume of the source/drain feature of the pull-up transistor comprises:
forming an opening exposing the source/drain feature of the pull-up transistor; and
performing an etching process to remove a portion of the source/drain feature of the pull-up transistor.

13. The method of claim 12, wherein the opening exposes a bottom surface of the source/drain feature of the pull-up transistor.

14. The method of claim 11, further comprising:
forming a first dielectric liner providing isolation between the first conductive feature and the substrate; and
forming a second dielectric liner providing isolation between the second conductive feature and the substrate.

15. The method of claim 11, wherein the pull-up transistor is a p-type transistor and comprises a plurality of nanostructures coupled to the source/drain feature of the pull-up transistor.

16. The method of claim 15, wherein the second conductive feature is disposed under the source/drain feature of the pull-up transistor, and a top surface of the second conductive feature is above a top surface of a bottommost nanostructure of the plurality of nanostructures.

17. A semiconductor structure, comprising:
a first transistor comprising a first source/drain feature;
a second transistor comprising a second source/drain feature;
a first conductive feature disposed under and electrically coupled to the first source/drain feature;
a second conductive feature disposed under and electrically coupled to the second source/drain feature;
wherein the first conductive feature and the second conductive feature have different depths.

18. The semiconductor structure of claim 17, wherein the first transistor is a pull-up transistor of a memory cell, the second transistor is a pull-down transistor of the memory cell, and a depth of the first conductive feature is greater than a depth of the second conductive feature.

19. The semiconductor structure of claim 18, wherein the first transistor comprises a plurality of nanostructures coupled to the first source/drain feature, and a top surface of the first conductive feature is above a top surface of a bottommost nanostructure of the plurality of nanostructures.

20. The semiconductor structure of claim 17, further comprising:
a dielectric liner extending along sidewall surfaces of the first conductive feature.
